(19) United States
(12) Patent Application Publication
(10) Pub. No.: US 2004/0246777 A1
(43) Pub. Date: Dec. 9, 2004

(54) Magnetic recording element and method of manufacturing magnetic recording element

(76) Inventors: Shinroku Maejima, Tokyo (JP); Shuichi Ueno, Tokyo (JP); Takashi Takenaga, Tokyo (JP); Takeharu Kuroiwa, Tokyo (JP)

Correspondence Address: MCDERMOTT, WILL & EMERY, 600 13th Street, N.W., Washington, DC, 20005-3096, US

(21) Appl. No.: 10/808,613

(22) Filed: Mar. 25, 2004

(30) Foreign Application Priority Data
Mar. 27, 2003 (JP) JP2003-088260

(51) Int. Cl. G11C 11/15

(52) U.S. Cl. 365/173; 365/171

(57) ABSTRACT

A photolithographic process using an X-direction delimiting mask (S11) for aligning respective side faces of a TMR element (1) and a strap (5) situated in a negative X side is performed, to shape the TMR element (1) and the strap (5) into desired configurations. The X-direction delimiting mask (S11) includes a straight edge and is disposed such that the straight edge is parallel to a Y direction and crosses both the TMR element (1) and the strap (5) in plan view. In use of the X-direction delimiting mask (S11), respective portions of the TMR element (1) and the strap (5) situated in a positive X side relative to the straight edge in plan view are covered with the X-direction delimiting mask (S11).

### BACKGROUND OF THE INVENTION

1. Field of the Invention

The present invention relates to magnetic storage techniques which can be applied to a magnetic storage device for storing data with the aid of giant magnetoresistive effects or tunneling magnetoresistive effects.

2. Description of the Background Art

Recently, advances have been made in studies for a nonvolatile magnetic random access memory (which will be hereinafter referred to as an “MRAM”) for enabling utilization of a tunneling magnetoresistive (which will be hereinafter referred to as a “TMR”) effect in a ferromagnetic tunnel junction. A typical TMR element includes a film with a trilayer structure including two ferromagnetic layers and one insulating layer interposed between the two ferromagnetic layers. In the typical TMR element, a tunneling current flowing in a direction perpendicular to a surface of the film differs depending on whether a direction of a magnetization of one of the two ferromagnetic layers is made parallel, or anti-parallel to, a direction of a magnetization of the other of the two ferromagnetic layers by application of an external magnetic field.

On the other hand, in the MRAM, to reduce a size of a memory cell for purposes of increasing an integration density results in increase of a reversing magnetic field under influence of a demagnetizing field depending on a dimension along a surface of a film of a magnetic layer. This would necessitate a strong magnetic field in a write operation, to increase power consumption. In this regard, a technique with optimizing a configuration of a ferromagnetic layer for facilitating reversal of a magnetization is proposed in Japanese Patent Application Laid-Open No. 2002-280637.

Utilization of a TMR element for an MRAM has suffered from the following problems. One problem is that inclusion of a margin for an error in alignment between the TMR element and a conductor connected to the TMR element is detrimental to reduction of a size of a memory cell. Further, due to the need for a strong magnetic field in a write operation for reducing a size of a memory cell, surroundings of a non-selected memory cell becomes more subject to influences of a magnetic field, which might invite another problem of erroneous recording.

### SUMMARY OF THE INVENTION

It is a first object of the present invention to reduce a margin for an error in alignment between a TMR element and a conductor connected to the TMR element. Also, it is a second object of the present invention to provide a technique for increasing a write magnetic field of a TMR element of a non-selected memory cell while suppressing a write magnetic field of another TMR element of a selected memory cell.

A magnetic recording element of the present invention includes a magnetic layer. The magnetic layer showing an S-shaped magnetization distribution when a strength of a magnetic field applied to the magnetic layer along a hard axis of the magnetic layer is higher than a threshold value. The magnetic layer shows a C-shaped magnetization distribution when the strength of the magnetic field applied to the magnetic layer along the hard axis is lower than the threshold value.

When a magnetic field with a strength lower than the threshold value is applied to the magnetic layer of the magnetic recording element along the hard axis thereof, a magnetization distribution shown by the magnetic layer can not be reversed without applying a magnetic field with a high strength to an easy axis of the magnetic layer. On the other hand, when a magnetic field with a strength higher than the threshold value is applied to the magnetic layer of the magnetic recording element along the hard axis thereof, a magnetization distribution shown by the magnetic layer can be reversed even with a magnetic field with a low strength being applied to the easy axis of the magnetic layer. Accordingly, by utilizing the magnetic recording element including the magnetic layer for a memory cell, it is possible to avoid occurrence of a disturbed cell.

A method of manufacturing a magnetic recording device of the present invention manufactures a magnetic recording element and a first conductor connected to the magnetic recording element. The method includes the step of shaping the magnetic recording element and the first conductor into desired configurations by performing a photolithographic process using one mask.

Also, the method of manufacturing a magnetic recording device makes it possible to reduce a margin for an error in alignment between the magnetic recording element and the conductor to approximately zero.

These and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a circuit diagram of a structure of a magnetic storage device according to a first preferred embodiment of the present invention.

FIG. 2 is a perspective view diagrammatically illustrating a structure of one memory cell.

FIG. 3 is a sectional view of a structure of a TMR element 1.

FIGS. 4A and 4B are sectional views diagrammatically illustrating a structure of a memory cell according to the first preferred embodiment of the present invention.

FIGS. 5A through 8B are sectional views for illustrating a method of manufacturing a magnetic storage device according to the first preferred embodiment of the present invention, in a sequential order.

FIGS. 9 and 10 are plan views for illustrating configurations of the TMR element 1 and a strap 5 and positional relationship between the TMR element 1 and the strap 5.

FIGS. 11A through 18B are sectional views for illustrating the method of manufacturing a magnetic storage device according to the first preferred embodiment of the present invention, in a sequential order.

FIG. 19 is a plan view for illustrating a method of manufacturing a magnetic storage device according to a second preferred embodiment of the present invention.

FIGS. 20A and 20B are sectional views of a structure of a magnetic storage device.

FIG. 21 is a plan view for illustrating a method of manufacturing a magnetic storage device according to a third preferred embodiment of the present invention.

FIGS. 22A and 22B are sectional views of a structure of a magnetic storage device.

FIG. 23 is a plan view for illustrating a method of manufacturing a magnetic storage device according to a fourth preferred embodiment of the present invention.

FIGS. 24A and 24B are sectional views of a structure of a magnetic storage device.

FIG. 25 is a plan view for illustrating a method of manufacturing a magnetic storage device according to a fifth preferred embodiment of the present invention.

FIGS. 26A and 26B are sectional views of a structure of a magnetic storage device.

FIGS. 27A through 30B are sectional views for illustrating a method of manufacturing a magnetic storage device according to a sixth preferred embodiment of the present invention, in a sequential order.

FIG. 31 is a plan view for illustrating a configuration of a Y-direction delimiting mask S20.

FIGS. 32A through 36B are sectional views for illustrating the method of manufacturing a magnetic storage device according to the sixth preferred embodiment of the present invention, in a sequential order.

FIGS. 37A through 39B are sectional views of structures of magnetic storage devices.

FIG. 40 is a graph for explaining occurrence of a disturbed cell.

FIG. 41 is a graph for showing asteroid curves exhibited by a rectangular magnetic layer.

FIG. 42 is a plan view of an example of a configuration of a recording layer 101 of a TMR element according to a seventh preferred embodiment of the present invention.

FIG. 43 is a graph for showing an asteroid curve exhibited by a magnetic layer according to the seventh preferred embodiment of the present invention.

FIGS. 44A and 44B are schematic views for illustrating C-shaped and S-shaped magnetization distributions.

FIG. 45 is a graph including plotted asteroid curves exhibited by the magnetic layer according to the seventh preferred embodiment of the present invention FIGS. 46, 47 and 48 are tables including plan views of categorized examples of a configuration of the magnetic layer according to the seventh preferred embodiment of the present invention.

FIGS. 49 and 50 are plan views for illustrating configurations of the TMR element 1 and the strap 5 and positional relationship between the TMR element 1 and the strap 5.

### DESCRIPTION OF THE PREFERRED EMBODIMENTS

First Preferred Embodiment

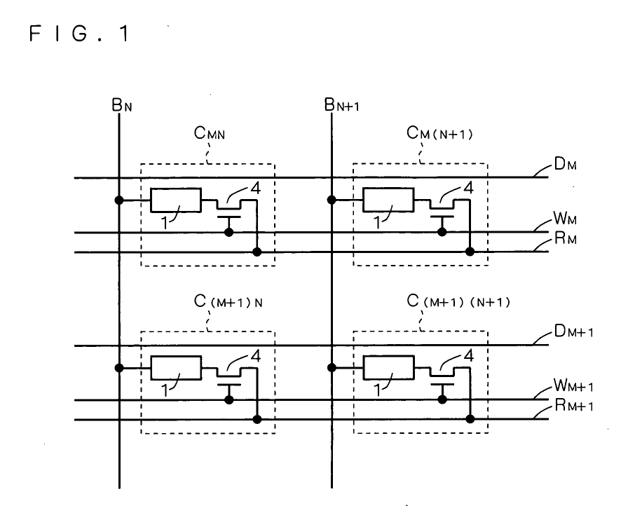

FIG. 1 is a circuit diagram illustrating a structure of a magnetic storage device according to a first preferred embodiment of the present invention. As illustrated in FIG. 1, the magnetic storage device according to the first preferred embodiment includes a plurality of bit lines B_{N} and B_{N+1} which are arranged along a longitudinal direction of a drawing sheet and a plurality of word lines W_{M} and W_{M+1} which are arranged along a horizontal direction of the drawing sheet. Further, a read line R_{M} and a digit line D_{M} are arranged along the word line W_{M}, and a read line R_{M+1} and a digit line D_{M+}are arranged along the word line W_{M+1} .

A memory cell C_{MN} is provided in the vicinity of an intersection between the bit line B_{N} and each of the word line W_{M}, the read line R_{M} and the digit line D_{M}. Also, a memory cell C_{M(N+1)} is provided in the vicinity of an intersection between a bit line B_{(N+1)} and each of the word line W_{M}, the read line R_{M} and the digit line D_{M}. Memory cells C_{(M+1)(N+1)} and C_{(M+1)N} are arranged in an analogous manner. Each of the memory cells C_{MN}, C_{M(N+1)}, C_{(M+1)(N+1)} and C_{(M+1)N} includes an access transistor 4 and a TMR element 1 functioning as a magnetic storage element. More bit lines, more word lines, more read lines and more digit lines can be provided so that the correspondingly increased number of memory cells can be arranged in a matrix array in the magnetic storage device.

A structure of the memory cell C_{MN} will be described as follows by way of example. The TMR element 1 includes one end connected to the bit line B_{N} and the other end connected to a drain of the access transistor 4. The access transistor 4 includes a source connected to the read line R_{M} and a gate connected to the word line W_{M}, in addition to the drain.

The digit line D_{M} and the bit line B_{N} extend in the vicinity of the TMR element 1. A direction of a magnetization of a predetermined ferromagnetic layer in the TMR element 1 is determined by a magnetic field generated by a current flowing through the digit line D_{M} and/or a current flowing through the bit line B_{N}. Thus, to cause a current to flow through the digit line D_{M} results in application of an external magnetic field to the TMR element 1 of each of the memory cells C_{MN} and C_{M(N+1)}. Also, to cause a current to flow through the bit line B_{N} results in application of an external magnetic field to the TMR element 1 of each of the memory cells C_{MN} and C_{M+1)N}. Then, the memory cell C_{MN} is selected by causing a current to flow through each of the digit line D_{M} and the bit line B_{N}, to accomplish a write operation on the TMR element 1 included in the memory cell C_{MN}. At that time, to ensure that a current flows through the bit line B_{N}, the access transistor 4 of each of the memory cells is turned off by applying a predetermined potential to the word lines W_{M} and W_{M+1}.

On the other hand, the access transistor 4 included in each of the memory cells C_{MN} and C_{M(N+1)} is turned on by applying another predetermined potential to the word line W_{M}. As a result, electrical conduction takes place not only from the TMR element 1 of the memory cell C_{MN} to the bit line B_{N}, but also from the TMR element 1 of the memory cell C_{MN} to the read line R_{M}. Also, electrical conduction takes place not only from the TMR element 1 of the memory cell C_{M(N+1)} to the bit line B_{(N+1)}, but also from the TMR element 1 of the memory cell C_{M(N+1)} to the read line R_{(M+1)}. Accordingly, the memory cell C_{MN} is selected by applying a predetermined potential to the bit line B_{N}, so that a current flows through the read line R_{M} from the TMR element 1 included in the memory cell C_{MN}.

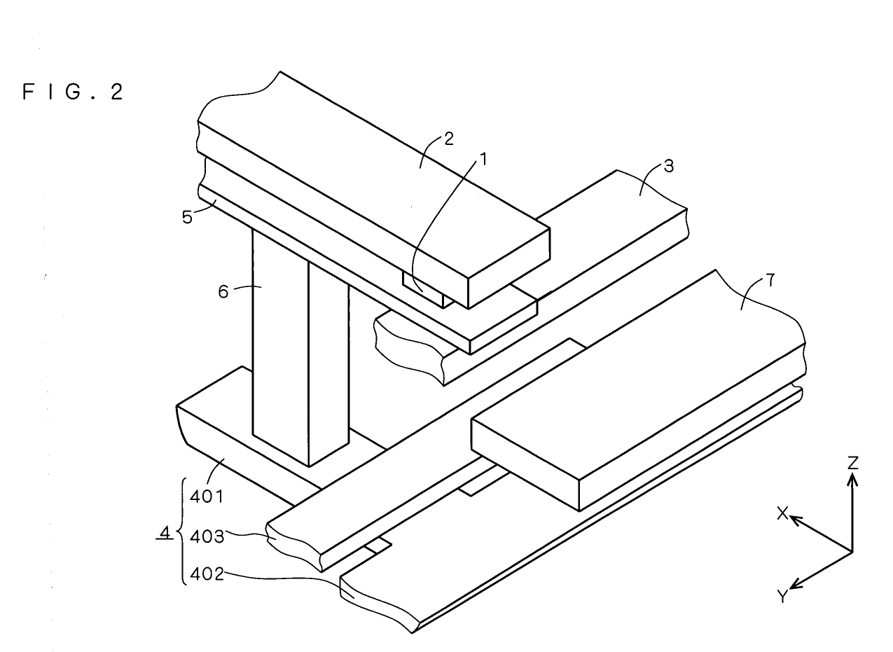

FIG. 2 is a perspective view diagrammatically illustrating a structure of one memory cell. It is noted that a right-handed coordinate system is employed in FIG. 2 and “X direction”, “Y direction” and “Z direction” in FIG. 2 are perpendicular to one another. A digit line 3, a read line 402 and a word line 403 extend along the Y direction. On the other hand, a bit line 2 and a strap 5 extend along the X direction. The strap 5, the TMR element 1 and the bit line 2 are sequentially deposited along a positive Z direction (a direction indicated by an arrow “Z” in FIG. 2, which will be hereinafter also considered as an “upward direction” for convenience's sake). Specifically, the TMR element 1 is situated in the positive Z side relative to the strap 5 while being in contact with the strap 5, and the bit line 2 is situated in the positive Z side relative to the TMR element 1 while being in contact with the TMR element 1. Also, the strap 5, the digit line 3 and the word line 403 are arranged along a negative Z direction (a direction opposite to the positive Z direction, which will hereinafter be also considered as a “downward” direction for convenience's sake). Specifically, the digit line 3 is situated in a negative Z side relative to the strap 5 while being spaced apart from the strap 5, and the word line 403 is situated in a negative Z side relative to the digit line 3 while being spaced apart from the digit line 3.

The access transistor 4 includes a gate electrode including the word line 403 (which will thus be hereinafter also referred to as a “gate 403”), a source including the read line 402 (which will thus be hereinafter also referred to as a “source 402”), and a drain 401. The drain 401 is connected to the strap 5 via a plug 6 extending along the Z direction. Each of the plug 6 and the strap 5 is conductive. An upper surface and a lower surface of the TMR element 1 correspond to the above-mentioned “one end” connected to the bit line and the above-mentioned “other end” connected to the drain of the access transistor 4, respectively.

Further, a metal layer 7 extending along the Y direction is provided. The metal layer 7 is connected to the source 402, at a portion thereof not illustrated, to make a parallel connection with a source resistance. Thus, the performance of the source 402 as a read line is improved. As such, if the source resistance is low, there is no need of providing the metal layer 7.

In the foregoing structure, an external magnetic field in a positive Y direction (a direction indicated by an arrow “Y” in FIG. 2) is applied to the TMR element 1 upon flow of a current through the bit line 2 in a positive X direction (a direction indicated by an arrow “X” in FIG. 2). Also, an external magnetic field in the positive X direction is applied to the TMR element 1 upon flow of a current through the digit line 3 in the positive Y direction.

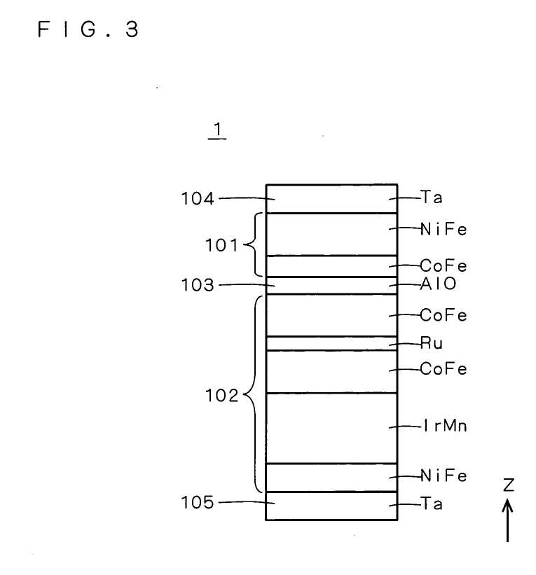

FIG. 3 is a sectional view of a structure of the TMR element 1. The TMR element 1 includes a layered structure in which a conductive layer 104, a recording layer 101, a tunnel insulating layer 103, an adhesion layer 102 and a conductive layer 105 are vertically deposited in the order of citation in this description with the conductive layer 104 being situated as the uppermost layer. For each of the conductive layers 104 and 105, a Ta film can be employed for example. For the recording layer 101, a layered structure including a CoFe film at upper side and a NiFe film at lower side can be employed for example. For the tunnel insulating layer 103, an AlO film can be employed for example. For the adhesion layer 102, a layered structure in which a CoFe film, a Ru film, a CoFe film, an IrMn film and a NiFe film are vertically deposited in the order of citation in this description with the first-cited CoFe film being situated as the uppermost layer can be employed for example. The adhesion layer 102 is fixedly magnetized in the positive Y direction, for example.

The first object of the present invention, to put it more concretely, is to reduce a margin for an error in alignment between the TMR element 1 and the strap 5, which margin is provided in the X direction and/or the Y direction, and/or to reduce a margin for an error in alignment between the TMR element 1 and the bit line 2, which margin is provided in the Y direction, for example.

The second object of the present invention, to put it more concretely, is to prevent the TMR element 1 from being erroneously written due to flow of a current through the bit line 2 in a memory cell in which no current is flowing through the digit line 3 (i.e., a non-selected memory cell) during a write operation. Such erroneous writing creates concern also in another memory cell in which no current is flowing through the bit line 2 while a current is flowing through the digit line 3. More specifically, in the structure illustrated in FIG. 1 for example, in a situation where a current is flowing through the digit line D_{M} and the bit line B_{N} and no current is flowing through the digit line D_{M+1} and the bit line B_{N+1}, there is concern that the memory cell C_{M+1)N} or the memory cell C_{M(N+1)} might be erroneously written.

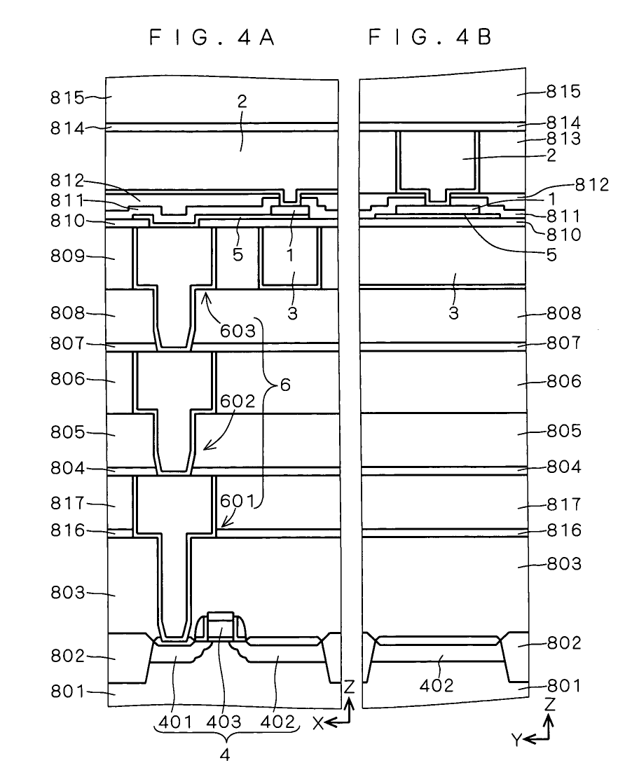

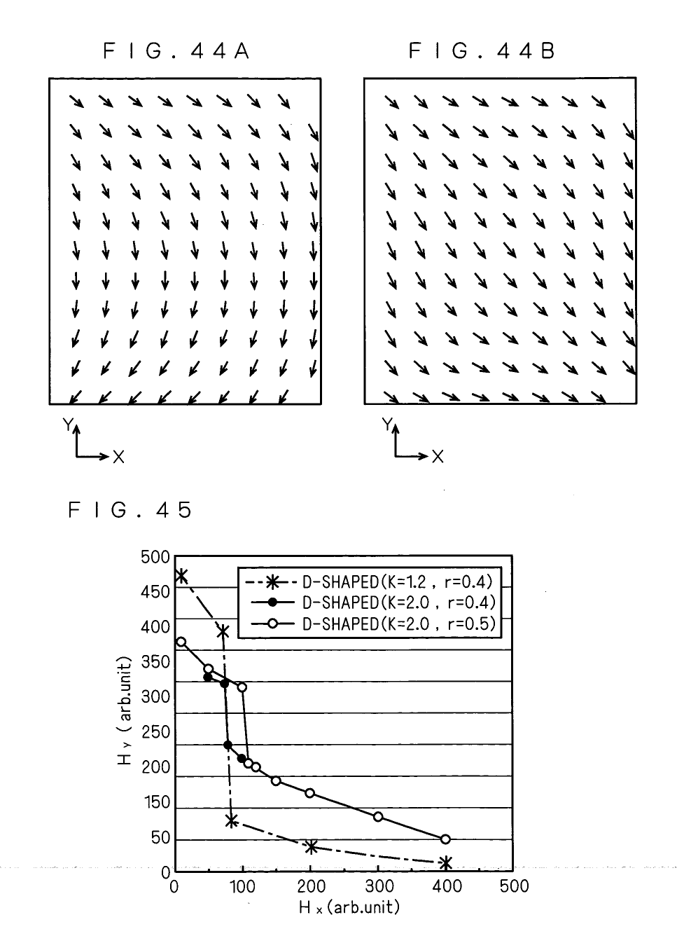

FIGS. 4A and 4B are sectional views diagrammatically illustrating a structure of a memory cell according to the first preferred embodiment. FIGS. 4A and 4B are sectional views of the memory cell according to the first preferred embodiment as it is viewed from a positive Y side to a negative Y side and from a negative X side to a positive X side, respectively. Such manner for illustration will be applied to all the accompanying figures except FIGS. 44A and 44B in this application. Specifically, each of the figures marked with a given number and “A” is a sectional view of a given structure as it is viewed from the positive Y side to the negative Y side, and each of the figures marked with a given number and “B” is a sectional view of a given structure as it is viewed from the negative X side to the positive X side. Also, it is noted that each of FIG. 4A and later illustrates an example in which the metal layer 7 is not provided.

Turning to FIGS. 4A and 4B, an isolation oxide film 802 and the access transistor 4 interposed between portions of the isolation oxide film 802 are provided on an upper surface of a semiconductor substrate 801. An upper surface of each of the drain 401, the source 402 and the gate 403 of the access transistor 4 is silicided.

Above the semiconductor substrate 801, an interlayer oxide film 803 in which the isolation oxide film 802 and the access transistor 4 are embedded is provided. Further, an interlayer nitride film 816, an interlayer oxide film 817, an interlayer nitride film 804, interlayer oxide films 805 and 806, an interlayer nitride film 807, interlayer oxide films 808 and 809 and an interlayer nitride film 810 are provided on the interlayer oxide film 803 in the order of citation in this description.

A plug 601 extending through the interlayer oxide film 803, the interlayer nitride film 816 and the interlayer oxide film 817, a plug 602 extending through the interlayer nitride film 804 and the interlayer oxide films 805 and 806, and a plug 603 extending through the interlayer nitride film 807 and the interlayer oxide films 808 and 809, are provided. The plugs 601, 602 and 603 come together to form a plug 6. Each of the plugs 601, 602 and 603 includes a metal layer with a barrier metal as an underlying material. The plug 6 with the foregoing structure can be formed by a known method utilizing what is called a damascene process.

The digit line 3 extends through the interlayer oxide film 809. The digit line 3 can be formed in the same step that is performed for forming a portion of the plug 603.

The strap 5 is provided on a portion of the interlayer nitride film 810 so as to extend from an upper side of the plug 6 to an upper side of the digit line 3. In this regard, the interlayer nitride film 810 includes an opening by which an upper surface of the plug 603 is exposed, so that the strap 5 and the plug 603 are connected to each other via the opening.

The TMR element 1 is provided on the strap 5 so as to be situated above the digit line 3. According to the first preferred embodiment, a side face of the strap 5 which is situated in the negative X side relative to any other portion in the strap 5 (it is noted that such side face will be hereinafter simply referred to as “a side face of the strap 5 in the negative X side”and similar expression will be used to mean similar situation) and a side face of the TMR element 1 in the negative X side are aligned to each other. Accordingly, a margin for an error in alignment between the strap 5 and the TMR element 1 in the X direction is substantially equal to zero.

The interlayer nitride film 810, the strap 5 and the TMR element 1 are crowned with an interlayer nitride film 811 and interlayer oxide films 812 and 813. In this regard, each of the interlayer nitride film 811 and the interlayer oxide film 812 includes an opening by which the upper surface of the TMR element 1 is exposed.

The interlayer oxide film 813 is provided on the interlayer oxide film 812, and the bit line 2 extends through the interlayer oxide film 813. The bit line 2 is connected to the upper surface of the TMR element 1 via the openings in the interlayer nitride film 811 and the interlayer oxide film 812. The bit line 2 includes a metal layer with a barrier metal as an underlying material, and can be formed by a known method utilizing what is called a damascene process.

Moreover, an interlayer nitride film 814 is provided on the interlayer oxide film 813 and the bit line 2, and an interlayer nitride film 815 is deposited on the interlayer nitride film 814.

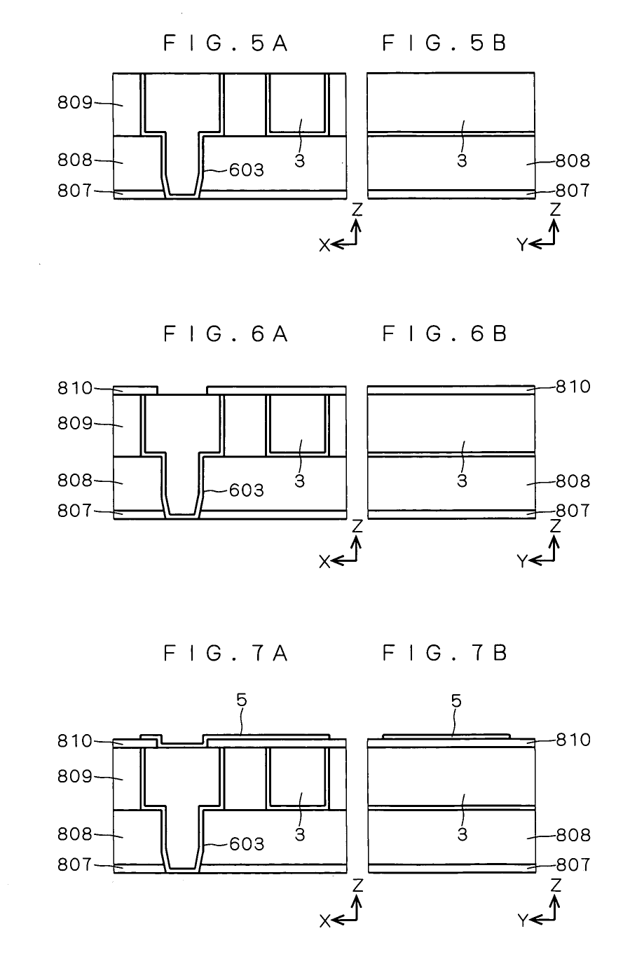

FIG. 5A through FIG. 8B are sectional views for illustrating a method of manufacturing a magnetic storage device according to the first preferred embodiment of the present invention, in a sequential order. It is noted that steps associated with manufacture of elements situated under the interlayer nitride film 807 are well-known, and thus description thereof are omitted.

First, the interlayer nitride film 807, and the interlayer oxide films 808 and 809 are sequentially deposited on the interlayer nitride film 807. Then, an opening used for forming a lower portion of the plug 603 is formed in each of the interlayer nitride film 807 and the interlayer oxide film 808. Further, an opening used for forming an upper portion of the plug 603 and the digit line 3 is formed in the interlayer oxide film 809. By employing a damascene process for example, it is possible to form the plug 603 and the digit line 3 each of which is flush with an upper surface of the interlayer oxide film 809 (FIGS. 5A and 5B).

Next, the interlayer nitride film 810 covering the interlayer oxide film 809, the plug 603 and the digit line 3 is formed. Subsequently, the opening by which the plug 603 is exposed is formed in the interlayer nitride film 810 (FIGS. 6A and 6B).

Then, the strap 5 is formed on a portion of the interlayer nitride film 810 so as to extend from an upper side of the plug 603 to the upper side of the digit line 3. The formation of the strap 5 can be achieved by once forming a metal layer on an entire surface of the interlayer nitride film 810 and the plug 603, and then performing a photolithographic process on the metal film using a predetermined mask adapted to form the strap 5 (which will hereinafter be referred to as a “strap mask”), for example. The strap 5 and the plug 603 are connected to each other via the opening in the interlayer nitride film 810 (FIGS. 7A and 7B).

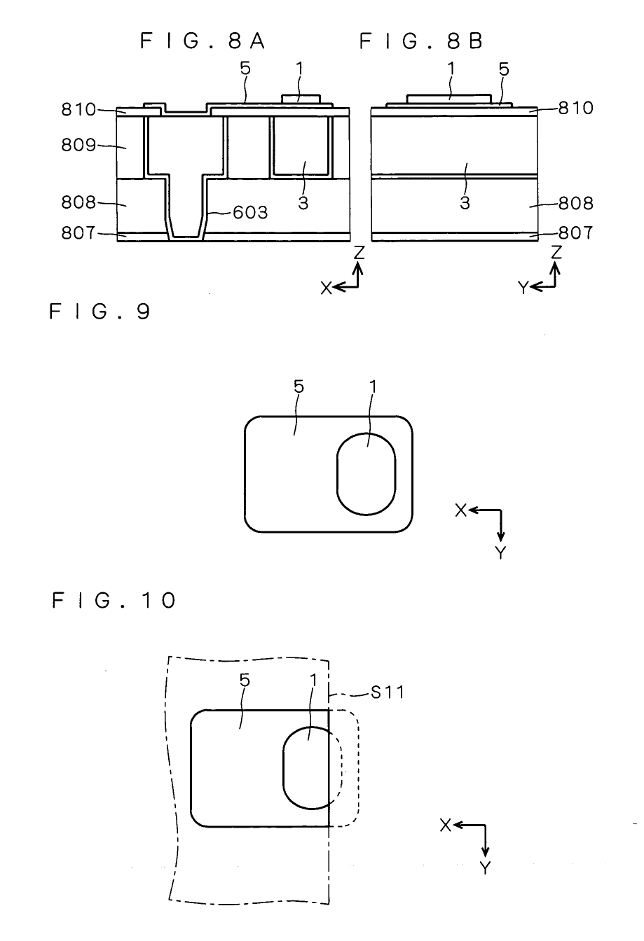

The TMR element 1 is formed on the strap 5 above the digit line 3. The formation of the TMR element 1 can be achieved by once forming the layered structure illustrated in FIG. 3 on an entire surface of the strap 5 and then performing a photolithographic process using a predetermined mask adapted to form the TMR element 1 (which will hereinafter be referred to as a “TMR mask”), for example (FIGS. 8A and 8B).

FIG. 9 is a plan view for illustrating configurations of the TMR element 1 and the strap 5 and positional relationship between the TMR element 1 and the strap 5, which are resulted from the step illustrated in FIGS. 8A and 8B. In the plan view of FIG. 9, the TMR element 1 and the strap 5 are illustrated as they are viewed from above (i.e., from the positive Z side to the negative Z side). In this stage, a side face of the TMR element 1 is not aligned to any side face of the strap 5 in the X direction, nor in the Y direction.

Thus, the TMR element 1 and the strap 5 are etched by utilizing a photolithographic process using a mask S11 adapted to align respective side faces of the TMR element 1 and the strap 5 in the negative X side to each other in plan view (which mask will be hereinafter referred to as an “X-direction delimiting mask S11”). FIG. 10 is a plan view for illustrating the X-direction delimiting mask S11, configurations of the TMR element 1 and the strap 5 which are provided after the etching using the X-direction delimiting mask S11, and positional relationship among the X-direction delimiting mask S11, the TMR element 1 and the strap 5. The X-direction delimiting mask S11 includes a straight edge. The X-direction delimiting mask S11 is disposed such that the straight edge is parallel to the Y direction and crosses both the TMR element 1 and the strap 5 in plan view. Also, in use of the X-direction delimiting mask S11, respective portions of the TMR element 1 and the strap 5 situated in the positive X side relative to the straight edge of the X-direction delimiting mask S11 in plan view are covered with the X-direction delimiting mask S11.

Then, the TMR element 1 and the strap 5 configured as illustrated in FIG. 9 are covered with a positive photoresist, and an exposure process and a development process are performed using the X-direction delimiting mask S11 disposed as illustrated in FIG. 10, to shape the photoresist into a configuration substantially identical to that of the X-direction delimiting mask S11. Accordingly, by etching the TMR element 1 and the strap 5 using the shaped photoresist as an etch mask, it is possible to shape the TMR element 1 and the strap 5 into the configurations illustrated in FIG. 10.

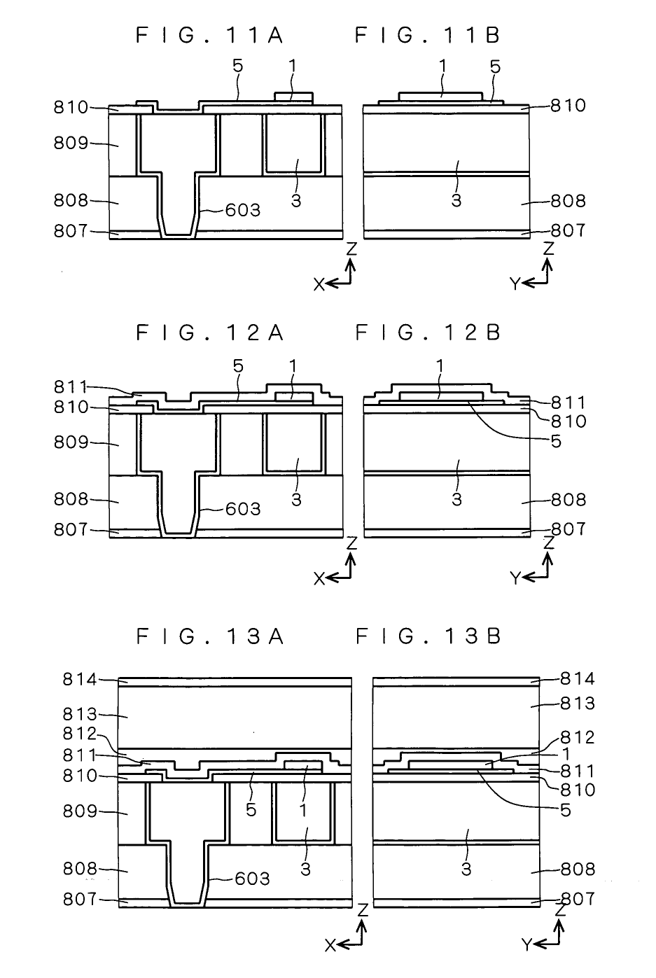

FIG. 11A through FIG. 18B are sectional views for illustrating steps performed after the photolithographic process using the X-direction delimiting mask S11 in the method of manufacturing a magnetic storage device according to the first preferred embodiment, in a sequential order. FIGS. 11A and 11B are sectional views of a structure provided after the TMR element 1 and the strap 5 are shaped by utilizing the photolithographic process using the X-direction delimiting mask S11 and then the photoresist used in the photolithographic process is removed. As illustrated in FIGS. 11A and 11B, the respective side faces of the TMR element 1 and the strap 5 in the negative X side are aligned to each other.

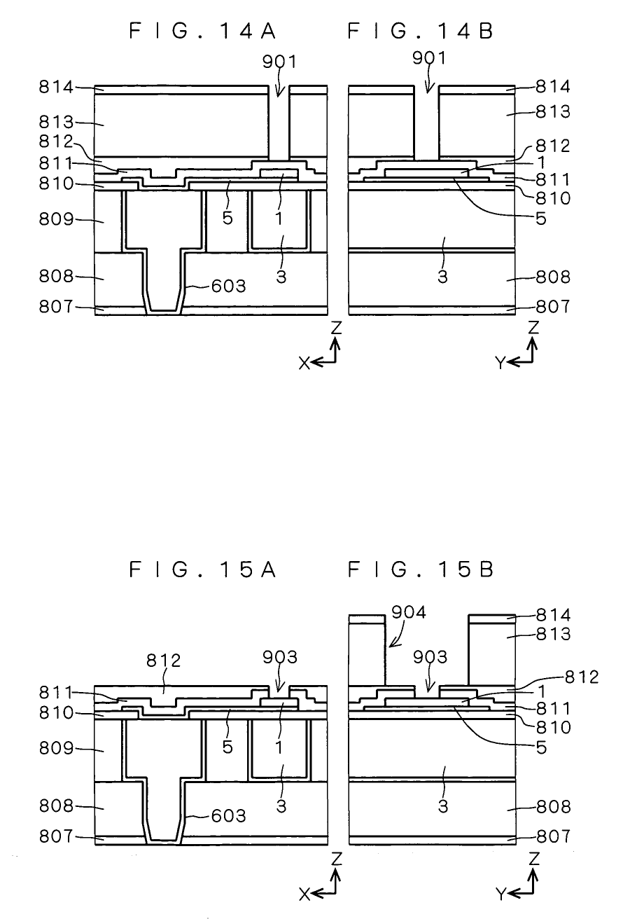

Next, the interlayer nitride film 811 is formed so as to cover the interlayer nitride film 810, the TMR element 1 and the strap 5 (FIGS. 12A and 12B). Further, the interlayer oxide film 812 is formed and is once planarized by performing a CMP (Chemical Mechanical Polish) process on the interlayer oxide film 812. Then, the interlayer oxide film 813 and the interlayer nitride film 814 are formed on the planarized interlayer oxide film 812 (FIGS. 13A and 13B).

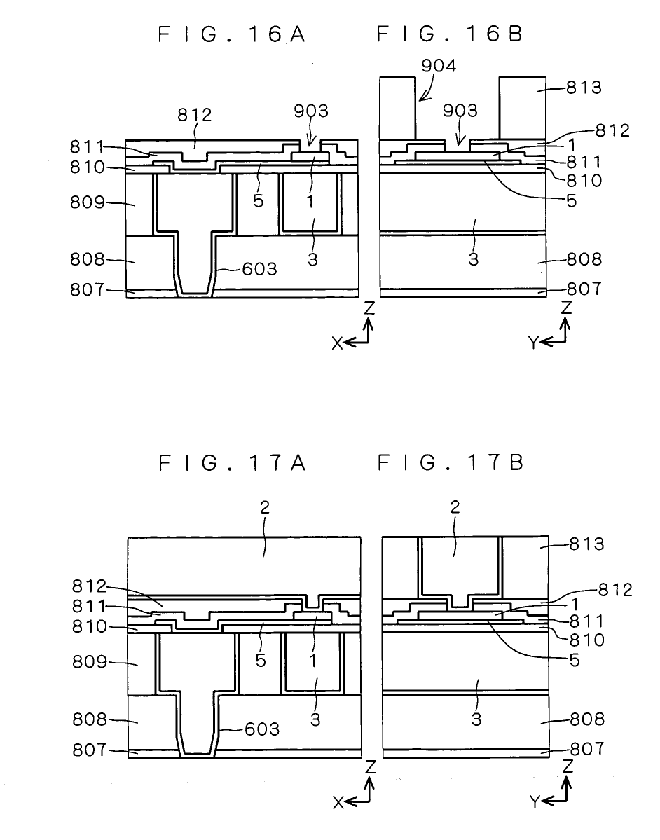

Thereafter, a portion of the interlayer nitride film 814 is selectively removed to form an opening. Also, the interlayer oxide films 812 and 813 are etched so that respective portions thereof are removed using the interlayer nitride film 814 including the opening, as a mask. As a result, an opening 901 extending through the interlayer oxide films 812 and 813 and the interlayer nitride film 814 is formed above the TMR element 1 (FIGS. 14A and 14B). Then, the interlayer nitride film 811 is etched, and further respective portions of the interlayer oxide film 813 and the interlayer nitride film 814 are selectively removed to widen the opening 901. This results in formation of an opening 904 which extends through the interlayer oxide film 813 and the interlayer nitride film 814 and is used for formation of the bit line 2. Also, an opening 903 having the same dimension as that of the opening 901 is left in the interlayer nitride film 811 and in the interlayer oxide film 812 (FIGS. 15A and 15B).

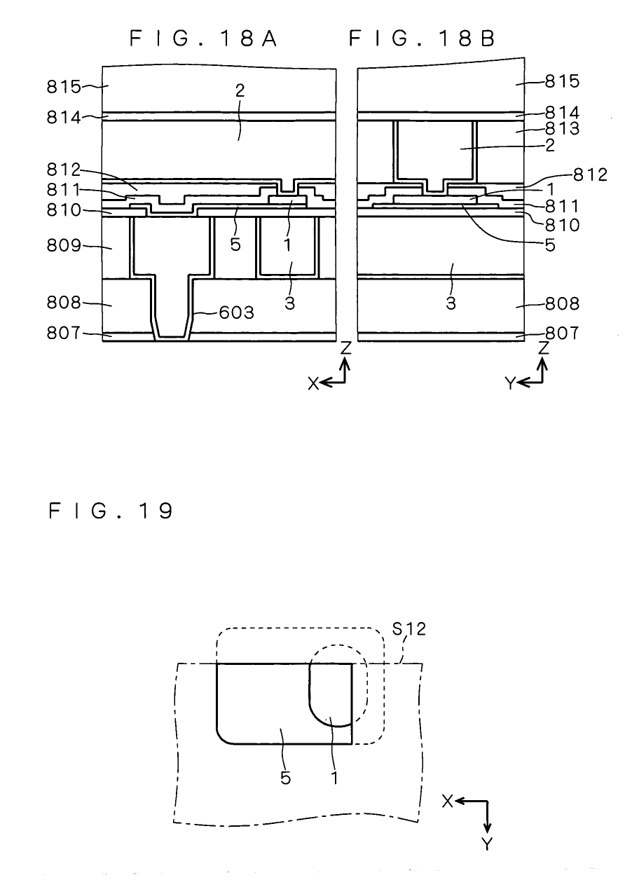

After that, the interlayer nitride film 814 which has been used as an etch mask for etching the interlayer oxide films 812 and 813 is once removed (FIGS. 16A and 16B). Subsequently, a damascene process is performed to form the bit line 2 (FIGS. 17A and 17B). Further, the interlayer nitride film 814 is again formed, and the interlayer nitride film 815 is formed on the interlayer nitride film 814 (FIGS. 18A and 18B). In this manner, a passivation film is formed on the bit line 2.

Additionally, it is preferable to form the interlayer nitride films 811, 814 and 815 and the interlayer oxide films 812 and 813 which are formed after the TMR element 1 is formed, at a low temperature.

As described above, according to the first preferred embodiment, it is possible to reduce a margin for an error in alignment between respective positions of the TMR element 1 and the strap 5 at the negative X side relative to any other portion (it is noted that such positions will be hereinafter referred to simply as “positions of the TMR element 1 and the strap 5 at the negative X side” and similar expression will be used to mean similar situation), to approximately zero by performing a photolithographic process on the TMR element 1 and the strap 5 using the X-direction delimiting mask S11 common to the TMR element 1 and the strap 5.

In particular, when the TMR mask is rectangular, to perform a photolithographic process using the TMR mask while disposing the TMR mask such that a longer side and a shorter side thereof are parallel to the Y direction and the X direction, respectively, would result in formation of the TMR element 1 with a configuration in which ends in the Y direction thereof draw almost semicircles (please refer to FIG. 9). By performing a photolithographic process on the TMR element 1 with such configuration while disposing the X-direction delimiting mask S11 such that the straight edge thereof is situated as described above, it is possible to shape the TMR element 1 into a configuration which is axially symmetrical with respect to an axis parallel to the X direction and is asymmetrical with respect to the Y direction. This configuration is suitable for attaining the second object of the present invention in carrying out a recording process by magnetizing the TMR element 1 in the Y direction. The first preferred embodiment is advantageous in that the TMR element 1 with the configuration illustrated in FIG. 10 can be easily manufactured, while advantages produced by that configuration of the TMR element 1 will be later described in more detail in a section of a seventh preferred embodiment.

In general, as a dimension of a device decreases, an accuracy required of a mask for shaping the device increases. As such, it is difficult to shape the device into a configuration which is axially symmetrical with respect to an axis parallel to one direction (the X direction in the example described above) and is asymmetrical with respect to another direction (the Y direction in the example described above) with the use of one photomask. According to the first preferred embodiment, photolithographic processes are performed using two photomasks, i.e., the TMR mask and the X-direction delimiting mask S11, respectively. This produces advantages of reducing a margin for an error in alignment between respective positions at the negative X side, as well as making it possible to easily manufacture the TMR element 1 with the foregoing configuration.

Additionally, though the above description has been made assuming a case where a positive photoresist is employed in performing the photolithographic process using the X-direction delimiting mask S11, a negative photoresist may alternatively be employed. Also in a case where the negative photoresist is employed, the X-direction delimiting mask S11 is disposed such that the straight edge thereof is parallel to the Y direction and crosses both the TMR element 1 and the strap 5 in plan view. However, unlike the case where the positive photoresist is employed, the X-direction delimiting mask S11 is disposed such that respective portions of the TMR element 1 and the strap 5 situated in the negative X side relative to the straight edge of the X-direction delimiting mask S11 in plan view are covered with the X-direction delimiting mask S11.

Further, the TMR element 1 and the strap 5 are not necessarily required to be etched in each of the photolithographic processes using the TMR mask and the X-direction delimiting mask S11, respectively. Alternatively, the following procedures may be employed. That is, first, the strap 5 is formed by a photolithographic process using the strap mask, and thereafter the layered structure which is to be shaped into the TMR element 1 is formed. Then, the layered structure is covered with a photoresist, and two exposure processes using the TMR mask and the X-direction delimiting mask S11, respectively, are performed on the same photoresist. Subsequently, a development process is performed, to thereby shape the photoresist into a configuration substantially identical to a configuration of an overlap region between the TMR mask and the X-direction delimiting mask S11.

Thus, by etching the TMR element 1 (the layered structure) and the strap 5 using the shaped photoresist as an etch mask, it is possible to shape the TMR element 1 and the strap 5 into the configurations illustrated in FIGS. 10A through 18B. Employment of this alternative procedure could simplify processes for formation of a photoresist, development and etching.

Second Preferred Embodiment

FIG. 19 is a plan view for illustrating a method of manufacturing a magnetic storage device according to a second preferred embodiment of the present invention. In the method according to the second preferred embodiment, the TMR element 1 and the strap 5 are further shaped after being shaped into the configurations illustrated in FIG. 10.

The TMR element 1 and the strap 5 are further etched by utilizing a photolithographic process using a mask S12 adapted to align respective side faces of the TMR element 1 and the strap 5 in a negative Y side to each other in plan view (which mask will be hereinafter referred to as an “negative-Y-direction delimiting mask S12”). FIG. 19 is a plan view for illustrating the negative-Y-direction delimiting mask S12, configurations of the TMR element 1 and the strap 5 which are provided after the etching using the negative-Y-direction delimiting mask S12 and positional relationship among the negative-Y-direction delimiting mask S12, the TMR element 1 and the strap 5. The negative-Y-direction delimiting mask S12 includes a straight edge. The negative-Y-direction delimiting mask S12 is disposed such that the straight edge is parallel to the X direction and crosses both the TMR element 1 and the strap 5 in plan view. Also, in use of the negative-Y-direction delimiting mask S12, respective portions of the TMR element 1 and the strap 5 situated in the positive Y side relative to the straight edge of the negative-Y-direction delimiting mask S12 in plan view are covered with the negative-Y-direction delimiting mask S12.

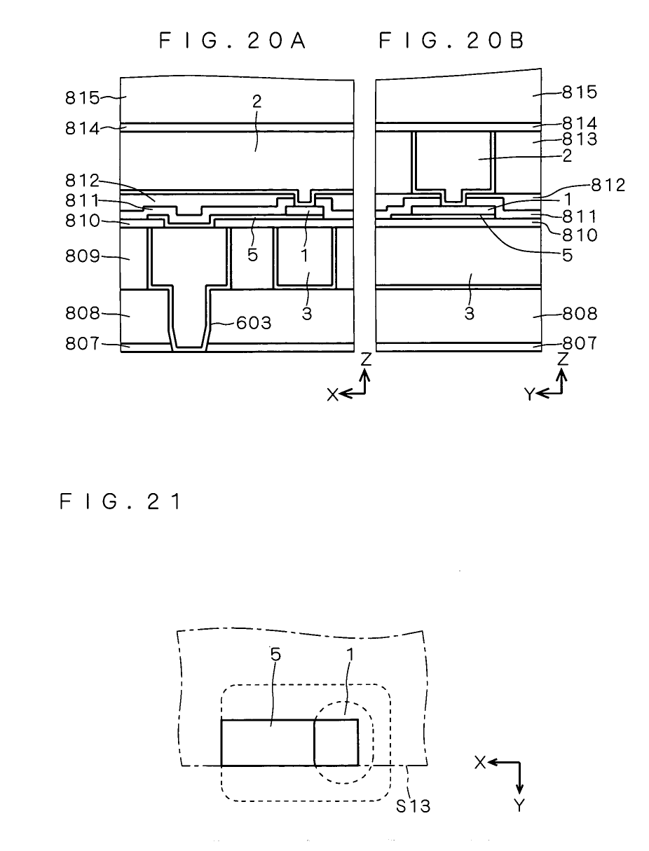

FIGS. 20A and 20B are sectional views of a structure of a magnetic storage device on which photolithographic processes are performed using the X-direction delimiting mask S11 and the negative-Y-direction delimiting mask S12. Not only respective side faces of the TMR element 1 and the strap 5 in the negative X side are aligned to each other as illustrated in FIG. 20A, but also respective side faces of the TMR element 1 and the strap 5 in the negative Y side are aligned to each other as illustrated in FIG. 20B.

As described above, according to the second preferred embodiment, it is possible to reduce a margin for an error in alignment between respective positions of the TMR element 1 and the strap 5 at the negative X side and a margin for an error in alignment between respective positions of the TMR element 1 and the strap 5 at the negative Y side, to approximately zero by performing photolithographic processes on the TMR element 1 and the strap 5 using the X-direction delimiting mask S11 and the negative-Y-direction delimiting mask S12.

Additionally, though the above description has been made assuming a case where a positive photoresist is employed in performing the photolithographic process using the negative-Y-direction delimiting mask S12, a negative photoresist may alternatively be employed. Also in a case where the negative photoresist is employed, the negative-Y-direction delimiting mask S12 is disposed such that the straight edge thereof is parallel to the X direction and crosses both the TMR element 1 and the strap 5 in plan view. However, unlike the case where the positive photoresist is employed, the negative-Y-direction delimiting mask S12 is disposed such that respective portions of the TMR element 1 and the strap 5 situated in the negative Y side relative to the straight edge of the negative-Y-direction delimiting mask S12 in plan view are covered with the negative-Y-direction delimiting mask S12.

Further, the TMR element 1 and the strap 5 are not necessarily required to be etched in each of the photolithographic processes using the X-direction delimiting mask S11 and the negative-Y-direction delimiting mask S12, respectively. Alternatively, the following procedures may be employed. That is, first, the TMR element 1 and the strap 5 which are in the state as illustrated in FIG. 9 are covered with a positive photoresist, and two exposure processes using the X-direction delimiting mask S11 and the negative-Y-direction delimiting mask S12, respectively, are performed on the same photoresist, Subsequently, a development process is performed, to thereby shape the photoresist into a configuration substantially identical to a configuration of an overlap region between the X-direction delimiting mask S11 and the negative-Y-direction delimiting mask S12.

Thus, by etching the TMR element 1 and the strap 5 using the shaped photoresist as an etch mask, it is possible to shape the TMR element 1 and the strap 5 into the configurations illustrated in FIGS. 19, 20A and 20B. Employment of this alternative procedure could simplify processes for formation of a photoresist, development and etching.

Moreover, three exposure processes using the TMR mask, the X-direction delimiting mask S11 and the negative-Y-direction delimiting mask S12, respectively, may be performed on the same photoresist in a manner similar to that described in the first preferred embodiment, which provides for further simplification of processes for formation of a photoresist, development and etching.

Third Preferred Embodiment

FIG. 21 is a plan view for illustrating a method of manufacturing a magnetic storage device according to a third preferred embodiment of the present invention. In the method according to the third preferred embodiment, the TMR element 1 and the strap 5 are further shaped after being shaped into the configurations illustrated in FIG. 19.

The TMR element 1 and the strap 5 are further etched by utilizing a photolithographic process using a mask S13 adapted to align between respective side faces of the TMR element 1 and the strap 5 in the positive Y side to each other in plan view (which mask will be hereinafter referred to as a “positive-Y-direction delimiting mask S13”). FIG. 21 is a plan view for illustrating the positive-Y-direction delimiting mask S13, configurations of the TMR element 1 and the strap 5 which are provided after the etching using the positive-Y-direction delimiting mask S13, and positional relationship among the positive-Y-direction delimiting mask S13, the TMR element 1 and the strap 5. The positive-Y-direction delimiting mask S13 includes a straight edge. The positive-Y-direction delimiting mask S13 is disposed such that the straight edge is parallel to the X direction and crosses both the TMR element 1 and the strap 5 in plan view. Also, in use of the positive-Y-direction delimiting mask S13, respective portions of the TMR element 1 and the strap 5 situated in the negative Y side relative to the straight edge of the positive-Y-direction delimiting mask S13 in plan view are covered with the positive-Y-direction delimiting mask S13.

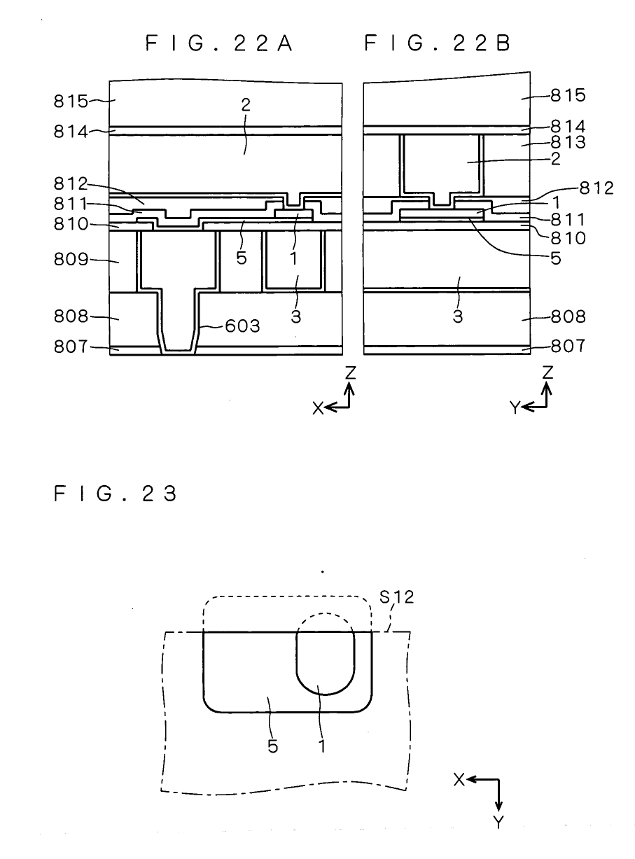

FIGS. 22A and 22B are sectional views of a structure of a magnetic storage device on which photolithographic processes are performed using the X-direction delimiting mask S11, the negative-Y-direction delimiting mask S12 and the positive-Y-direction delimiting mask S13. As illustrated in FIG. 22A, respective side faces of the TMR element 1 and the strap 5 in the negative X side are aligned to each other. Also, respective side faces of the TMR element 1 and the strap 5 in the negative Y side are aligned to each other, and further, respective side faces of the TMR element 1 and the strap 5 in the positive Y side are aligned to each other, as illustrated in FIG. 22B.

As described above, according to the third preferred embodiment, it is possible to reduce a margin for an error in alignment between respective positions of the TMR element 1 and the strap 5 at the negative X side and margins for errors in alignment between respective positions of the TMR element 1 and the strap 5 at the negative Y side and the positive Y side, to approximately zero by performing a photolithographic process on the TMR element 1 and the strap 5 using the X-direction delimiting mask S11, the negative-Y-direction delimiting mask S12 and the positive-Y-direction delimiting mask S13.

Additionally, though the above description has been made assuming a case where a positive photoresist is employed in performing the photolithographic process using the positive-Y-direction delimiting mask S13, a negative photoresist may alternatively be employed. Also in a case where the negative photoresist is employed, the positive-Y-direction delimiting mask S13 is disposed such that the straight edge thereof is parallel to the X direction and crosses both the TMR element 1 and the strap 5 in plan view. However, unlike the case where the positive photoresist is employed, the positive-Y-direction delimiting mask S13 is disposed such that respective portions of the TMR element 1 and the strap 5 situated in the positive Y side relative to the straight edge of the positive-Y-direction delimiting mask S13 in plan view are covered with the positive-Y-direction delimiting mask S13.

Further, the TMR element 1 and the strap 5 are not necessarily required to be etched in each of the photolithographic processes using the X-direction delimiting mask S11, the negative-Y-direction delimiting mask S12 and the positive-Y-direction delimiting mask S13, respectively. Alternatively, the following procedures may be employed. That is, first, the TMR element 1 and the strap 5 which are in the state as illustrated in FIG. 9 are covered with a positive photoresist, and three exposure processes using the X-direction delimiting mask S11, the negative-Y-direction delimiting mask S12 and the positive-Y-direction delimiting mask S13, respectively, are performed on the same photoresist, Subsequently, a development process is performed, to thereby shape the photoresist into a configuration substantially identical to a configuration of an overlap region among the X-direction delimiting mask S11, the negative-Y-direction delimiting mask S12 and the positive-Y-direction delimiting mask S13.

Thus, by etching the TMR element 1 and the strap 5 using the shaped photoresist as an etch mask, it is possible to shape the TMR element 1 and the strap 5 into the configurations illustrated in FIGS. 21, 22A and 22B. Employment of this alternative procedure could simplify processes for formation of a photoresist, development and etching.

Moreover, four exposure processes using the TMR mask, the X-direction delimiting mask S11, the negative-Y-direction delimiting mask S12 and the positive-Y-direction delimiting mask S13, respectively, may be performed on the same photoresist in a manner similar to that described in the first preferred embodiment, which provides for further simplification of processes for formation of a photoresist, development and etching.

Fourth Preferred Embodiment

FIG. 23 is a plan view for illustrating a method of manufacturing a magnetic storage device according to a fourth preferred embodiment of the present invention. In the method according to the fourth preferred embodiment, the TMR element 1 and the strap 5 are further shaped after being shaped into the configurations illustrated in FIG. 9.

FIG. 23 is a plan view for illustrating the negative-Y-direction delimiting mask S12, configurations of the TMR element 1 and the strap 5 which are provided after the etching using the negative-Y-direction delimiting mask S12 and positional relationship among the negative-Y-direction delimiting mask S12, the TMR element 1 and the strap 5. The negative-Y-direction delimiting mask S12 includes the straight edge. The negative-Y-direction delimiting mask S12 is disposed such that the straight edge is parallel to the X direction and crosses both the TMR element 1 and the strap 5 in plan view. Also, in use of the negative-Y-direction delimiting mask S12, respective portions of the TMR element 1 and the strap 5 situated in the positive Y side relative to the straight edge of the negative-Y-direction delimiting mask S12 in plan view are covered with the negative-Y-direction delimiting mask S12.

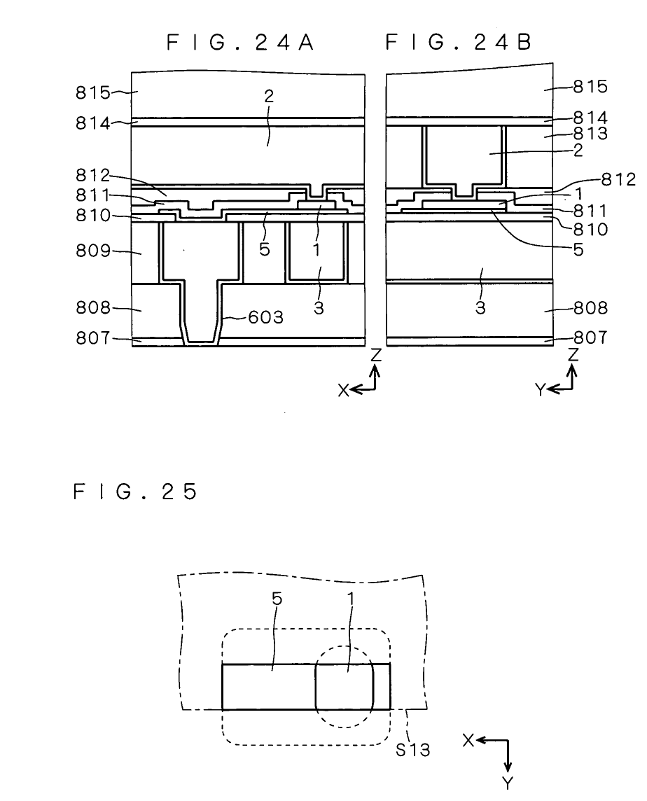

FIGS. 24A and 24B are sectional views of a structure of a magnetic storage device on which a photolithographic process is performed using the negative-Y-direction delimiting mask S12. As illustrated in FIG. 24B, respective side faces of the TMR element 1 and the strap 5 in the negative Y side are aligned to each other.

As described above, according to the fourth preferred embodiment, it is possible to reduce a margin for an error in alignment between respective positions of the TMR element 1 and the strap 5 at the negative Y side to approximately zero by performing a photolithographic process on the TMR element 1 and the strap 5 using the negative-Y-direction delimiting mask S12.

Additionally, though the above description has been made assuming a case where a positive photoresist is employed in performing the photolithographic process using the negative-Y-direction delimiting mask S12, a negative photoresist may alternatively be employed.

Further, the TMR element 1 and the strap 5 are not necessarily required to be etched in each of the photolithographic processes using the TMR mask and the negative-Y-direction delimiting mask S12, respectively. Alternatively, the following procedures may be employed. That is, first, the strap 5 is formed by a photolithographic process using the strap mask, and thereafter the layered structure which is to be shaped into the TMR element 1 is formed. Then, the layered structure is covered with a photoresist, and two exposure processes using the TMR mask and the negative-Y-direction delimiting mask S12, respectively, are performed on the same photoresist. Subsequently, a development process is performed, to thereby shape the photoresist into a configuration substantially identical to a configuration of an overlap region between the TMR mask and the negative-Y-direction delimiting mask S12.

Thus, by etching the TMR element 1 (the layered structure) and the strap 5 using the shaped photoresist as an etch mask, it is possible to shape the TMR element 1 and the strap 5 into the configurations illustrated in FIG. 23, 24A and 24B. Employment of this alternative procedure could simplify processes for formation of a photoresist, development and etching.

Fifth Preferred Embodiment

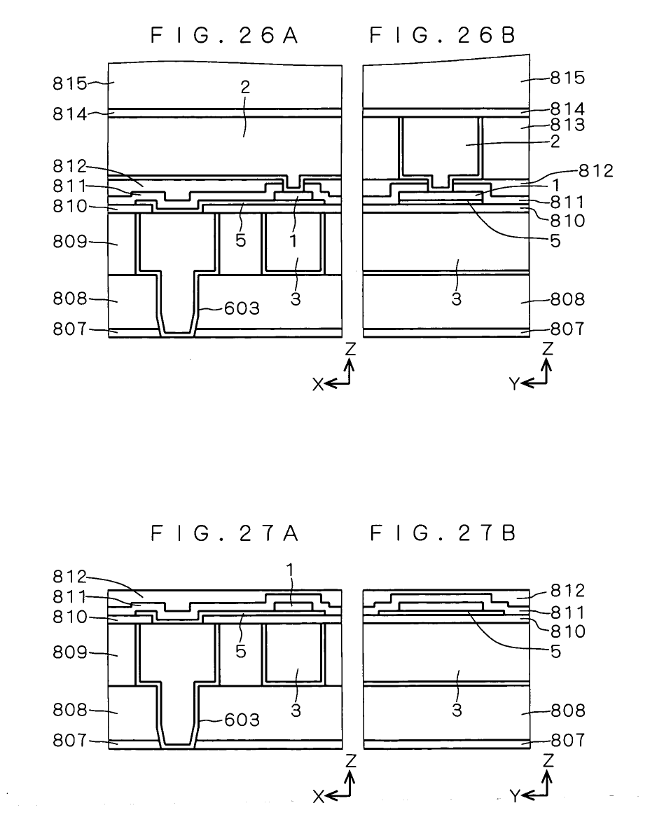

FIG. 25 is a plan view for illustrating a method of manufacturing a magnetic storage device according to a fifth preferred embodiment of the present invention. In the method according to the fifth preferred embodiment, the TMR element 1 and the strap 5 are further shaped after being shaped into the configurations illustrated in FIG. 23.

FIG. 25 is a plan view for illustrating the positive-Y-direction delimiting mask S13, configurations of the TMR element 1 and the strap 5 which are provided after the etching using the positive-Y-direction delimiting mask S13 and positional relationship among the positive-Y-direction delimiting mask S13, the TMR element 1 and the strap 5. The positive-Y-direction delimiting mask S13 includes the straight edge. The positive-Y-direction delimiting mask S13 is disposed such that the straight edge is parallel to the X direction and crosses both the TMR element 1 and the strap 5 in plan view. Also, in use of the positive-Y-direction delimiting mask S13, respective portions of the TMR element 1 and the strap 5 situated in the negative Y side relative to the straight edge of the positive-Y-direction delimiting mask S13 in plan view are covered with the positive-Y-direction delimiting mask S13.

FIGS. 26A and 26B are sectional views of a structure of a magnetic storage device on which photolithographic processes are performed using the negative-Y-direction delimiting mask S12 and the positive-Y-direction delimiting mask S13. As illustrated in FIG. 26B, not only respective side faces of the TMR element 1 and the strap 5 in the negative Y side, but also respective side faces of the TMR element 1 and the strap 5 in the positive X side are aligned to each other.

As described above, according to the fifth preferred embodiment, it is possible to reduce margins for an error in alignment between respective positions of the TMR element 1 and the strap 5 at each of the negative Y side and the positive Y side to approximately zero by performing photolithographic processes on the TMR element 1 and the strap 5 using the negative-Y-direction delimiting mask S12 and the positive-Y-direction delimiting mask S13.

Additionally, though the above description has been made assuming a case where a positive photoresist is employed in performing the photolithographic process using the positive-Y-direction delimiting mask S13, a negative photoresist may alternatively be employed.

Further, the TMR element 1 and the strap 5 are not necessarily required to be etched in each of the photolithographic processes using the negative-Y-direction delimiting mask S12 and the positive-Y-direction delimiting mask S13, respectively. Alternatively, the following procedures may be employed. That is, first, the TMR element 1 and the strap 5 which are in the state as illustrated in FIG. 9 are covered with a positive photoresist, and two exposure processes using the negative-Y-direction delimiting mask S12 and the positive-Y-direction delimiting mask S13, respectively, are performed on the same photoresist. Subsequently, a development process is performed, to thereby shape the photoresist into a configuration substantially identical to a configuration of an overlap region between the negative-Y-direction delimiting mask S12 and the positive-Y-direction delimiting mask S13.

Thus, by etching the TMR element 1 and the strap 5 using the shaped photoresist as an etch mask, it is possible to shape the TMR element 1 and the strap 5 into the configurations illustrated in FIGS. 25, 26A and 26B. Employment of this alternative procedure could simplify processes for formation of a photoresist, development and etching.

Moreover, three exposure processes using the TMR mask, the negative-Y-direction delimiting mask S12 and the positive-Y-direction delimiting mask S13, respectively, may be performed on the same photoresist in a manner similar to that described in the first preferred embodiment, which provides for further simplification of processes for formation of a photoresist, development and etching.

Sixth Preferred Embodiment

In a case where at lease one of the negative-Y-direction delimiting mask S12 and the positive-Y-direction delimiting mask S13 is employed, it is possible to reduce also a margin for an error in alignment of the TMR element 1 to the bit line 2 to approximately zero. This is achieved by performing a photolithographic process using a predetermined mask in etching for formation of the bit line 2, in place of employing a damascene process.

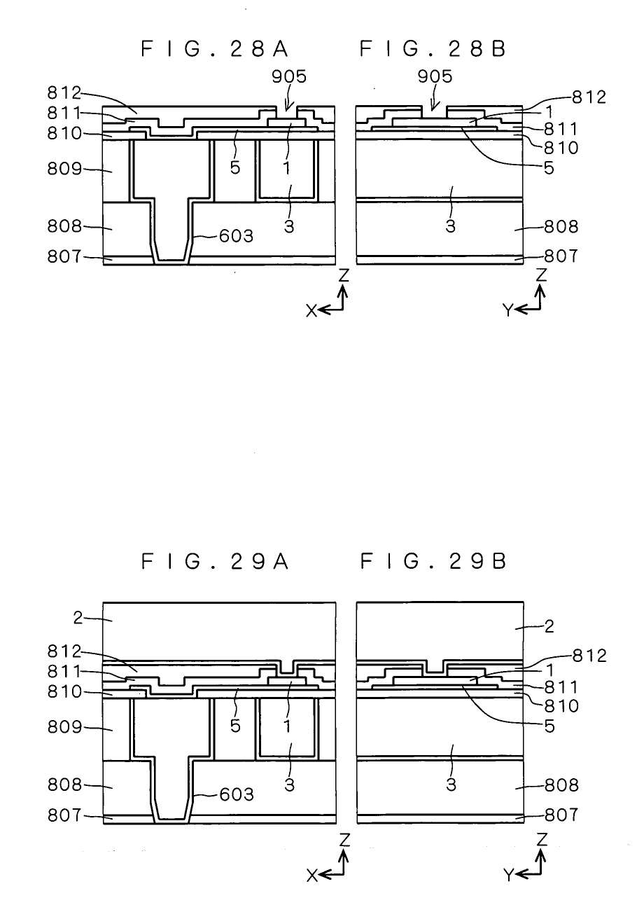

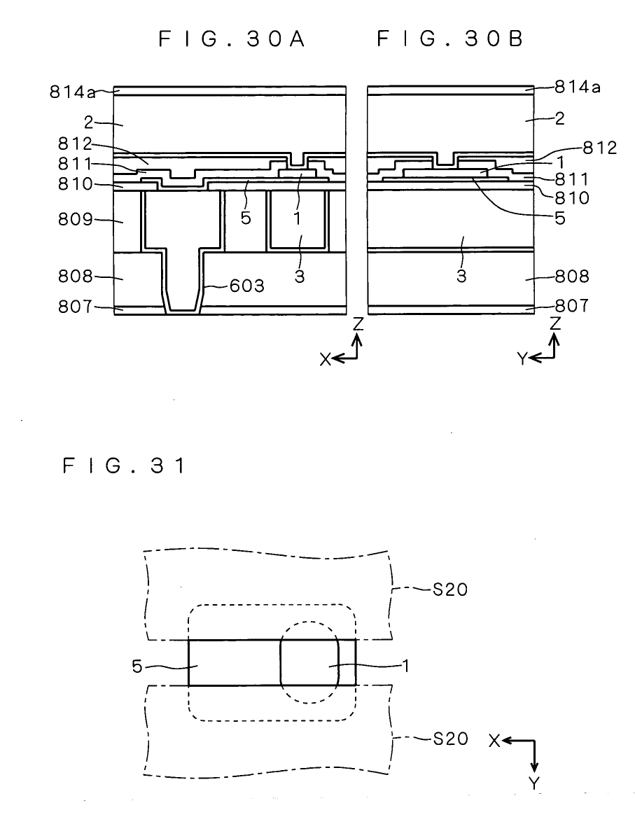

FIGS. 27A through 30B are sectional views for illustrating a method of manufacturing a magnetic storage device according to a sixth preferred embodiment of the present invention in a sequential order. The manufacturing method according to the sixth preferred embodiment is as follows. First, after the structure illustrated in FIG. 12 is obtained, the interlayer oxide film 812 is formed on an entire surface of the structure illustrated in FIG. 12. Subsequently, a CMP process is performed, to planarize an upper surface of the interlayer oxide film 812 (FIGS. 27A and 27B). Next, respective portions of the interlayer nitride film 811 and the interlayer oxide film 812 are selectively removed, to form an opening 905 by which the upper surface of the TMR element 1 is exposed (FIGS. 28A and 28B). Then, the bit line 2 is once formed on an entire surface of a structure provided after the formation of the opening 905 (FIGS. 29A and 29B). As a result, the opening 905 is filled with the bit line 2, which is thus connected to the upper surface of the TMR element 1. Thereafter, an interlayer nitride film 814a is formed on the bit line 2 (FIGS. 30A and 30B).

FIG. 31 is a plan view for illustrating a configuration of a Y-direction delimiting mask S20 used for pattering the interlayer nitride film 814a. In the plan view of FIG. 31, the TMR element 1 and the strap 5 are additionally illustrated for clarification purposes. The Y-direction delimiting mask S20 includes two straight edges which are parallel to each other. The Y-direction delimiting mask S20 is disposed such that the interlayer nitride film 814a which is not illustrated in FIG. 31 is exposed by a space defined by the two straight edges of the Y-direction delimiting mask S20. The Y-direction delimiting mask S20 is also disposed such that each of the two straight edges thereof is parallel to the X direction and crosses both the TMR element 1 and the strap 5. Thus, by performing an exposure process on a positive photoresist covering the interlayer nitride film 814a using the Y-direction delimiting mask S20 and subsequently performing a development process, it is possible to shape the photoresist into a configuration substantially identical to the Y-direction delimiting mask S20. Then, the interlayer nitride film 814a is etched using the shaped photoresist as an etch mask, to shape the interlayer nitride film 814a into a desired configuration.

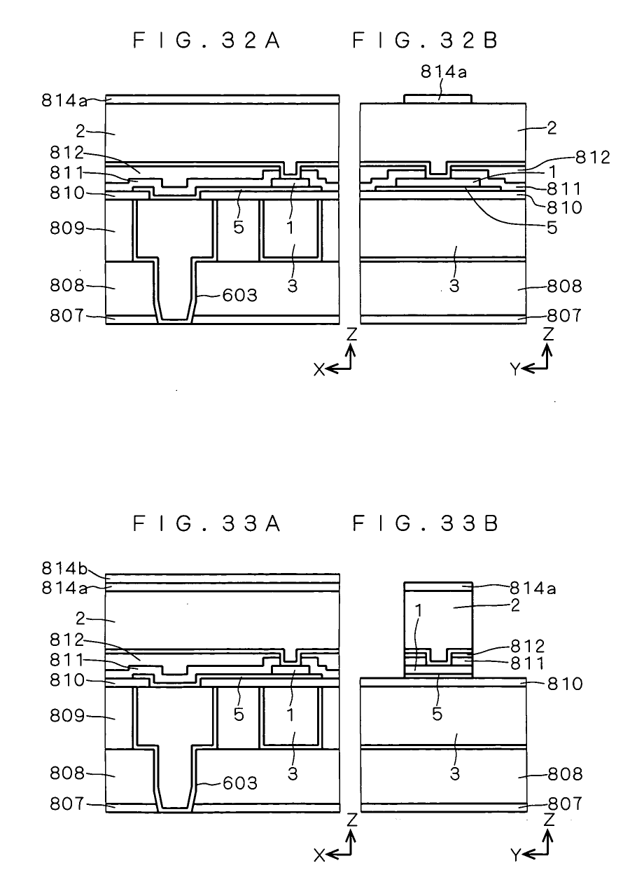

FIGS. 32A through 36B are sectional views for illustrating steps performed after the photolithographic process using the Y-direction delimiting mask S20 in the method of manufacturing a magnetic storage device according to the sixth preferred embodiment, in a sequential order. FIGS. 32A and 32B are sectional views of structures provided after the interlayer nitride film 814a is shaped into a desired configuration and the photoresist is removed. Next, the bit line 2, the TMR element 1 and the strap 5 are etched using the shaped interlayer nitride film 814a as a mask, so that each of the bit line 2, the TMR element 1 and the strap 5 is shaped into a configuration identical to that of the interlayer nitride film 814a (FIGS. 33A and 33B). The TMR element 1 is self-aligned to not only the strap 5 but also the bit line 2. Hence, it is possible to reduce a margin for an error in alignment among respective positions of the bit line 2, the TMR element 1 and the strap 5 in the Y direction, to approximately zero.

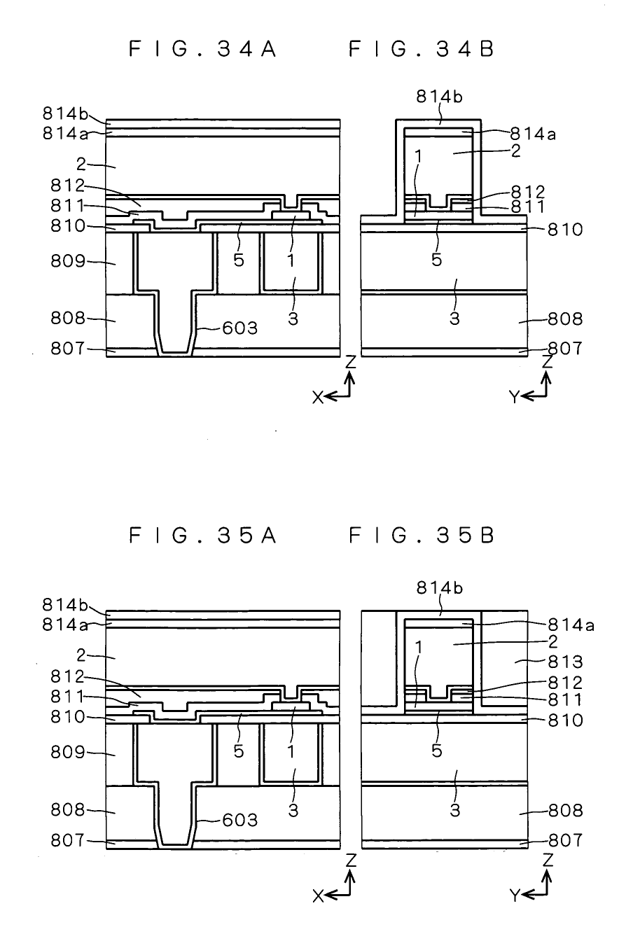

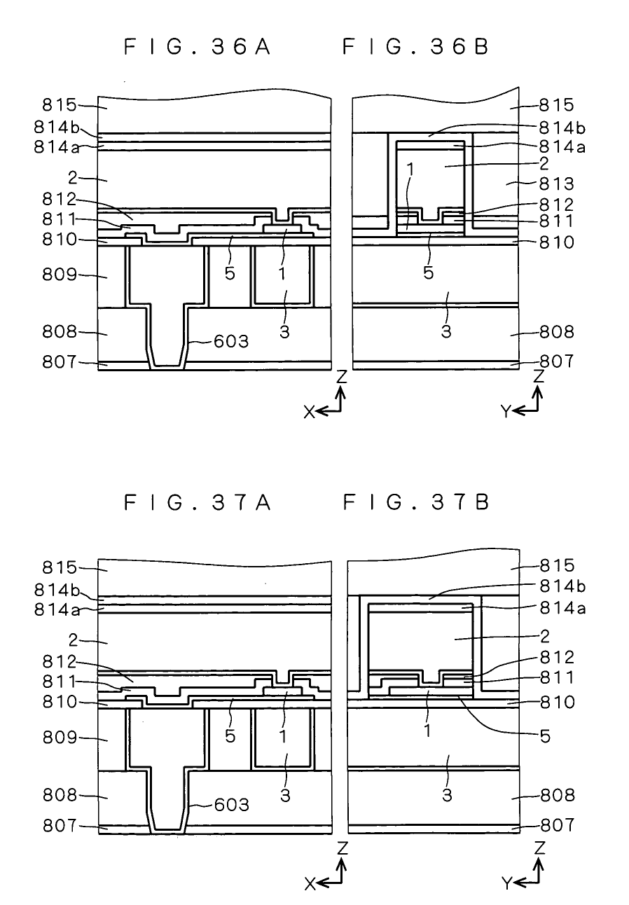

Thereafter, an interlayer nitride film 814b is formed on the interlayer nitride films 810 and 814a, and respective side faces of the bit line 2, the TMR element 1, the strap 5, the interlayer oxide film 812 and the interlayer nitride films 811 and 814a (FIGS. 34A and 34B). Then, the interlayer oxide film 813 is formed on the interlayer nitride film 814b, and a CMP process is performed on the interlayer oxide film 813 using the interlayer nitride film 814b as a stopper. This eliminates unevenness in a surface formed of respective surfaces of the interlayer oxide film 813 and the interlayer nitride film 814b (FIGS. 35A and 35B). Further, the interlayer nitride film 815 is formed on the interlayer oxide film 813 and the interlayer nitride film 814a (FIGS. 36A and 36B). In this manner, a passivation film is formed on the bit line 2.

As described above, according to the sixth preferred embodiment, a photolithographic process is performed on not only the TMR element 1 and the strap 5 but also the bit line 2 using the same Y-direction delimiting mask S20. As a result, it is possible to reduce a margin for an error in alignment among respective positions of the TMR element 1, the strap 5 and the bit line 2 in the Y direction to approximately zero.

It is additionally noted that though the above description has been made assuming a case where a positive photoresist is employed in performing the photolithographic process using the Y-direction delimiting mask S20, a negative photoresist may be employed. In a case where the negative photoresist is employed, a mask covering a portion of the interlayer nitride film 814a which is interposed between two straight lines parallel to the X direction is employed, and the mask is disposed so as to cross both the TMR element 1 and the strap 5 in plan view.

Further, as a first alternative method, the interlayer nitride film 814a may be shaped into a desired configuration by performing a photolithographic process using the negative-Y-direction delimiting mask S12 in the same manner as described in the fourth preferred embodiment. In the first alternative method, by etching the bit line 2, the TMR element 1 and the strap 5 using the shaped interlayer nitride film 814a as a mask, it is possible to allow the bit line 2, the TMR element 1 and the strap 5 to be self-aligned to one another, as well as to reduce a margin for an error in alignment among respective positions in the negative Y direction to approximately zero. As a result of employing the first alternative method, the TMR element 1 and the strap 5 are shaped into the configurations as illustrated in FIG. 23 in plan view. Also, FIGS. 37A and 37B are sectional views of a structure in which the bit line 2, the TMR element 1 and strap 5 which are shaped by employing the first alternative method and then the interlayer nitride film 815 is formed.

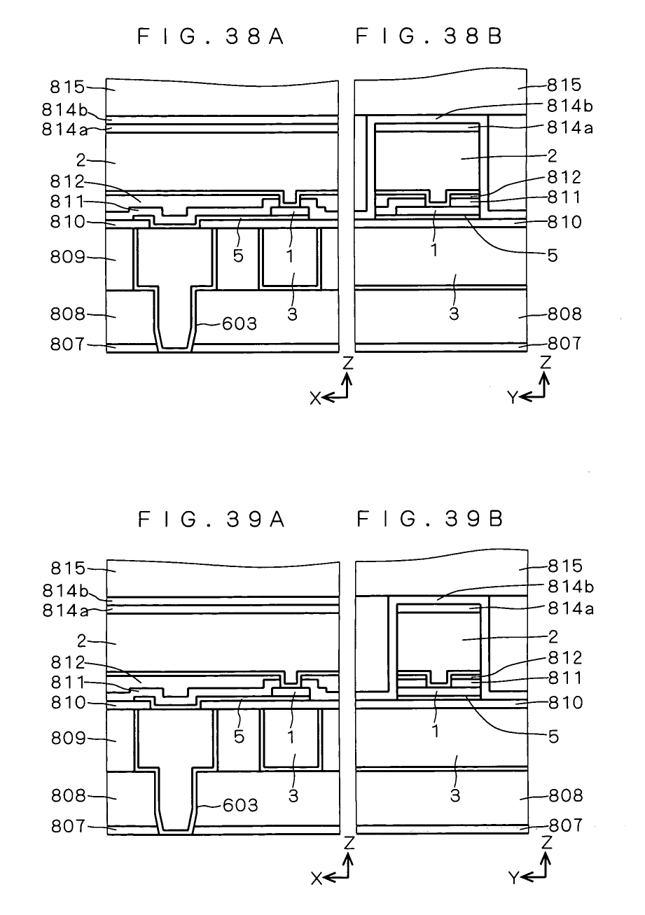

Moreover, as a second alternative method, the interlayer nitride film 814a may be shaped into a desired configuration by performing a photolithographic process using the X-direction delimiting mask S11 and the negative-Y-direction delimiting mask S12 in the same manner as described in the second preferred embodiment. In the second alternative method, by etching the bit line 2, the TMR element 1 and the strap 5 using the shaped interlayer nitride film 814a as a mask, it is possible to allow the bit line 2, the TMR element 1 and the strap 5 to be self-aligned to one another, and to reduce a margin for an error in alignment among respective positions at each of the negative X side and the negative Y side, to approximately zero. As a result of employing the second alternative method, the TMR element 1 and the strap 5 are shaped into the configurations as illustrated in FIG. 19 in plan view. Further, FIGS. 38A and 38B are sectional views of a structure in which the bit line 2, the TMR element 1 and strap 5 which are shaped by employing the second alternative method and then the interlayer nitride film 815 is formed.

As a third alternative method, the interlayer nitride film 814a may be shaped into a desired configuration by performing a photolithographic process using the X-direction delimiting mask S11, the negative-Y-direction delimiting mask S12 and the positive-Y-direction delimiting mask S13 in the same manner as described in the third preferred embodiment. In the third alternative method, by etching the bit line 2, the TMR element 1 and the strap 5 using the shaped interlayer nitride film 814a as a mask, it is possible to allow the bit line 2, the TMR element 1 and the strap 5 to be self-aligned to one another, and to reduce a margin for an error in alignment among respective positions at each of the negative X side, the negative Y side and the positive Y side, to approximately zero. As a result of employing the third alternative method, the TMR element 1 and the strap 5 are shaped into the configurations as illustrated in FIG. 21 in plan view. Further, FIGS. 39A and 39B are sectional views of structures in which the bit line 2, the TMR element 1 and strap 5 which are shaped by employing the third alternative method and then the interlayer nitride film 815 is formed.

Seventh Preferred Embodiment

According to a seventh preferred embodiment, a technique for avoiding occurrence of a disturbed cell is provided. Referring to FIG. 1, first, consider a situation where a current flows through the digit line D_{M} and the bit line B_{N} and no current flows through the bit line B_{N+1} during a write operation. A magnetic field generated by the bit line B_{N} affects also the memory cell C_{M(N+1)}. As such, when a large current flows through the digit line D_{M} or the bit line B_{N}, there is a good possibility that the memory cell C_{M(N+1)} might be erroneously written.

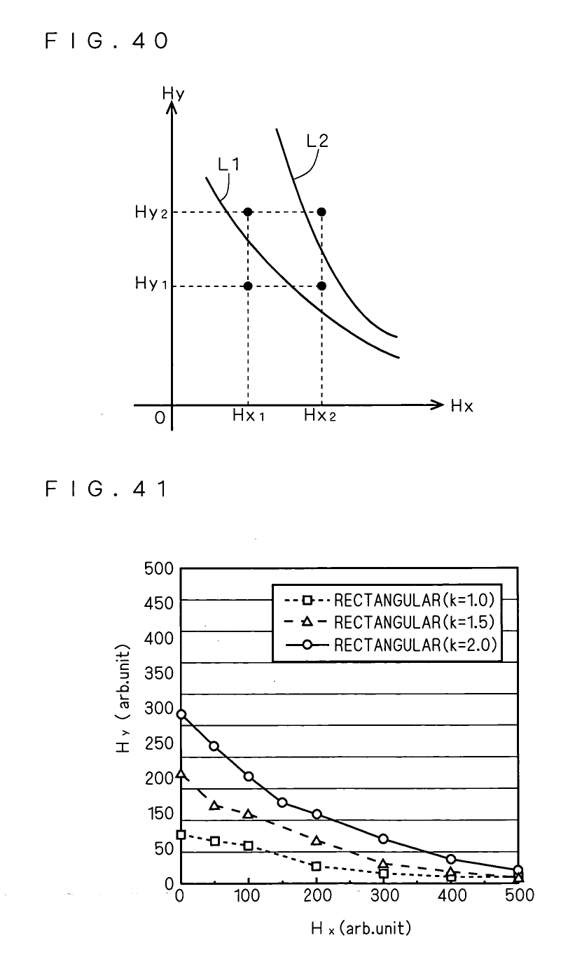

FIG. 40 is a graph for explaining occurrence of a disturbed cell described as above. In the graph of FIG. 40, two asteroid curves L1 and L2 of the recording layer 101 are shown relative to a magnetic field Hx applied to the TMR element 1 in the negative X direction and a magnetic field Hy applied to the TMR element 1 in the negative Y direction. As the TMR element 1 is magnetized in the Y direction to achieve a recording operation, an easy axis and a hard axis of the TMR element 1 are along the Y direction and the X direction, respectively. When a point (Hx, Hy) representing the magnetic fields Hx and Hy applied to the TMR element 1 is located closer to the original point O than the asteroid curve, no influence is exerted on the direction of the magnetization of the recording layer 101. Conversely, when the point (Hx, Hy) is located further from the original point O than the asteroid curve, influence is exerted on the direction of the magnetization of the recording layer 101. In the latter situation, even if the recording layer 101 of the TMR element 1 has been previously magnetized in the positive Y direction, the direction of the magnetization is reversed so that the recording layer 101 of the TMR element 1 is magnetized in the negative Y direction.

Upon flow of a current through the digit line 3 illustrated in FIG. 2 (corresponding to the digit line D_{M} in FIG. 1) in the positive Y direction, the magnetic field Hx in the positive X direction is applied to one of the TMR elements 1 situated just above the digit line 3 (the TMR element 1 of each of the memory cells C_{MN} and C_{M(N+1)} in FIG. 1). Also, upon flow of a current through the bit line 2 (the bit line B_{N} in FIG. 1) in the positive X direction, the magnetic field Hy in the positive Y direction is applied to one of the TMR elements 1 situated just under the bit line 2 (the TMR element 1 of the memory cell C_{MN} in FIG. 1). It is possible to avoid occurrence of a disturbed cell by setting the strength of the magnetic field Hx applied to the TMR element 1 situated just above the digit line 3 through which a current flows, to Hx₁ in a situation where the recording layer 101 exhibits the asteroid curve L1, the magnetic field Hy applied to the TMR element 1 situated just under the bit line 2 through which a current flows has a strength of Hy₂, and the magnetic field Hy applied to another TMR element 1 which is not situated just under the bit line 2 through which a current flows has a strength of Hy₁.

On the other hand, it is preferable that the strength of the magnetic field Hx applied to the TMR element 1 situated just above the digit line 3 through which a current flows is set higher to provide a large operating margin of a memory cell. However, to set the strength of the magnetic field Hx to Hx₂ (>Hx₁) would allow a write operation to take place even when the strength of the magnetic field Hy is Hy₁, so that also the TMR element 1 which is not situated just under the bit line 2 through which a current flows is written. To avoid occurrence of a disturbed cell, the recording layer 101 is required to exhibit the asteroid curve L2 which includes a slope steeper than that of the asteroid curve L1 around the employed magnetic field Hx. To pay attention to the asteroid curve L2 would reveal that, under conditions that the strength of the magnetic field Hx applied to the recording layer 101 is set to Hx₂, the direction of the magnetization of the recording layer 101 does not change when the magnetic field Hy with the strength of Hy, is applied while the direction of the magnetization of the recording layer 101 changes when the magnetic field Hy with the strength of Hy₂ is applied.

In view of the foregoing, one solution to steepen the slope of the asteroid curve under conditions that the strength of the magnetic field Hx in the direction along the hard axis is kept relatively low is to configure a magnetic layer such that a dimension along a hard axis thereof is smaller than a dimension along an easy axis thereof. FIG. 41 is a graph showing asteroid curves exhibited by NiFe functioning as a magnetic layer with a rectangular when a dimension along an easy axis of the NiFe is varied while a thickness and a dimension along a hard axis of the NiFe are fixed. A horizontal axis and a vertical axis of the graph represent respective strengths of the magnetic fields Hx and Hy, respectively, in an arbitrary unit. Further, “k” in the graph represents an aspect ratio obtained by dividing the dimension along the easy axis by the dimension along the hard axis. As the aspect ratio k increases, the slope of the asteroid curve becomes steeper. However, increase of the aspect ratio k is not preferable for the purposes of reducing a size of a device.

In this regard, given with the configuration which is axially symmetrical with respect to an axis parallel to the X direction (along a hard axis) and is asymmetrical with respect to the Y direction (along an easy axis) as described in the first preferred embodiment by making reference to FIG. 10, it is possible to considerably steepen a slope of its asteroid curve even if an aspect ratio is small.

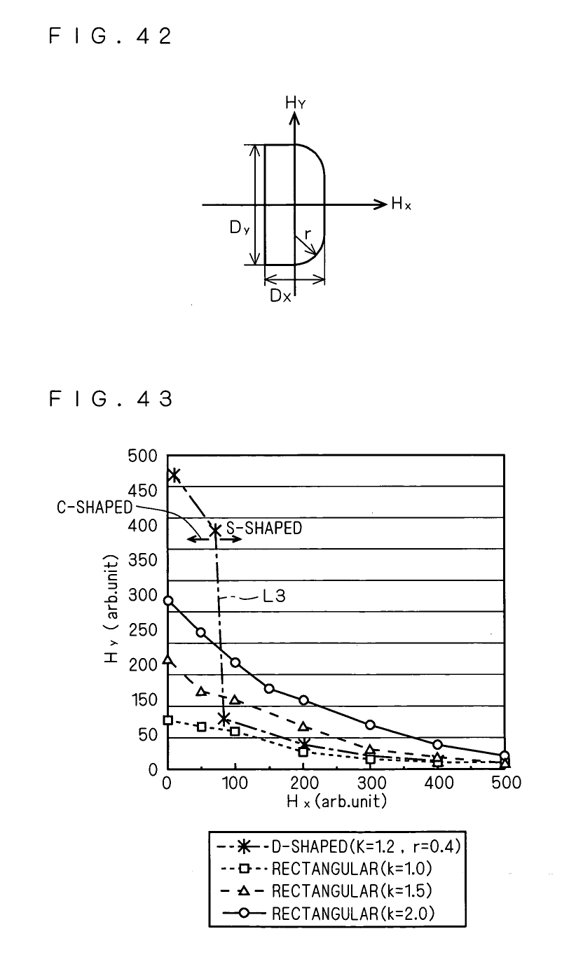

FIG. 42 is a plan view for illustrating an example of a configuration of the recording layer 101 of a TMR element according to the seventh preferred embodiment. In the plan view of FIG. 42, the recording layer 101 is illustrated as it is viewed from above (i.e., from the positive Z side to the negative Z side). Also, in FIG. 42, “Dx” and “Dy” indicate widths along a hard axis and an easy axis of the recording layer 101, respectively, and thus, an aspect ratio K of the recording layer 101 is represented by “Dy/Dx” for convenience's sake. In the example illustrated in FIG. 42, the recording layer 101 has a D-shaped configuration which is approximately rectangular but includes two circular comers. A radius of each of the two circular comers is represented by “r”. One of the two comers corresponds to a meeting point of a side situated in the positive X side relative to any other side and a side situated in the positive Y side relative to any other side, and the other of the two comers corresponds to a meeting point of a side situated in the positive X side relative to any other side and a side situated in the negative Y side relative to any other side. It is noted that the radius r will be normalized using the width Dx of the hard axis in the following description.

FIG. 43 is a graph which includes an asteroid curve L3 exhibited by a magnetic layer with the D-shaped configuration illustrated in FIG. 42, in addition to the same asteroid curves as included in the graph of FIG. 41, which are exhibited by the rectangular magnetic layer. The asteroid curve L3 in FIG. 43 is obtained in an example where the aspect ratio K and the radius r of the D-shaped magnetic layer are set to 1.2 and 0.4, respectively. Further, a thickness of NiFe and a dimension along a hard axis of the D-shaped magnetic layer are set to the same values as those of the rectangular magnetic layer which exhibits the asteroid curves in the graph of FIG. 41.

When the strength of the magnetic field Hx is higher than approximately 80 (in an arbitrary unit), the asteroid curve L3 substantially overlaps the asteroid curve exhibited by the rectangular magnetic layer with the aspect ratio k of 1.0. On the other hand, when the strength of the magnetic field Hx is equal to approximately 80 (in an arbitrary unit), the slope of the asteroid curve L3 is extremely steep. When the strength of the magnetic field Hx is lower than 80 (in an arbitrary unit), the strength of the magnetic field Hy on the asteroid curve L3 is much higher than that on the asteroid curve exhibited by the rectangular magnetic layer with the aspect ratio k of 2.0.

Thus, by controlling the respective strengths Hx₁ and Hx₂ in FIG. 40 applied to the TMR element 1 including the recording layer 101 which exhibits the asteroid curve L3 to be lower and higher than 80 (in an arbitrary unit), respectively, it is possible to avoid occurrence of a disturbed cell. Further, such approach is less detrimental to reduction of a size than to employ a rectangular configuration.

Reasons for such a steep slope of the asteroid curve as shown in FIG. 43 lie in a change of a state of a magnetization of a magnetic layer which occurs when the strength of the magnetic field Hx becomes equal to a certain threshold value (80(in an arbitrary unit) in the example shown in FIG. 43). More specifically, when a magnetic field with a strength lower than the certain threshold value is applied to a magnetic layer along a hard axis thereof, a so-called C-shaped magnetization distribution is achieved, while when a magnetic field with a strength higher than the certain threshold value is applied to a magnetic layer along a hard axis thereof, a so-called S-shaped magnetization distribution is achieved.

FIGS. 44A and 44B are schematic views illustrating magnetization distributions. FIG. 44A is a schematic view of the C-shaped magnetization distribution and FIG. 44B is a schematic view of the S-shaped magnetization distribution. Each of the magnetization distributions illustrated in FIGS. 44A and 44B is obtained by setting the strength of the magnetic field Hy to 0, by way of example. When the strength of the magnetic field Hx is lower than the threshold value, magnetization along an easy axis in which a magnetization in the X direction is weak occurs as illustrated in FIG. 44A (in the example illustrated in FIG. 44A, magnetization in the negative Y direction occurs as a whole). In the C-shaped magnetization distribution, the strength of the magnetic field Hy required to reverse a magnetization is high, so that an asteroid curve including such a steep slope as described above can be obtained.

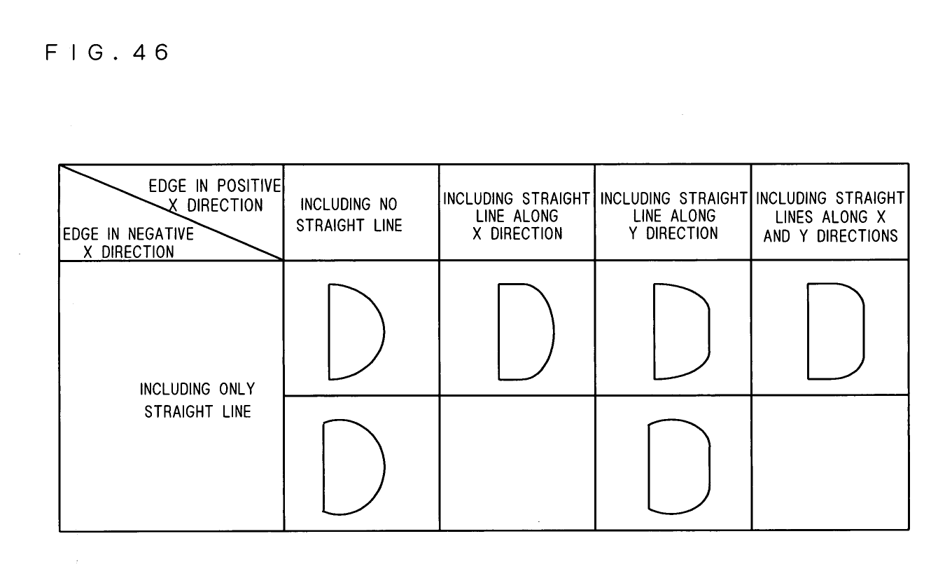

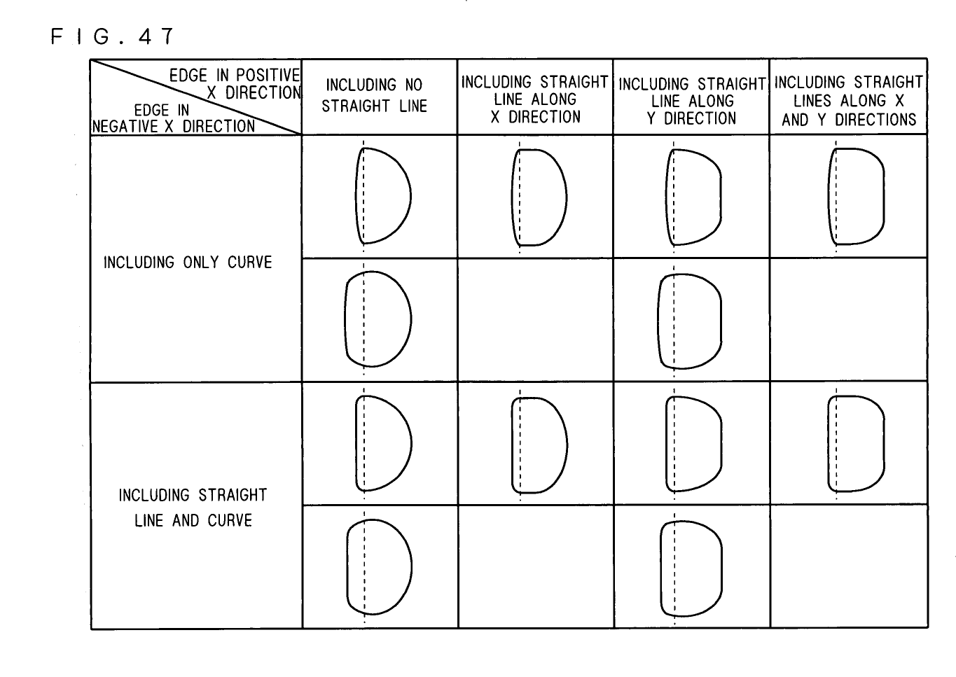

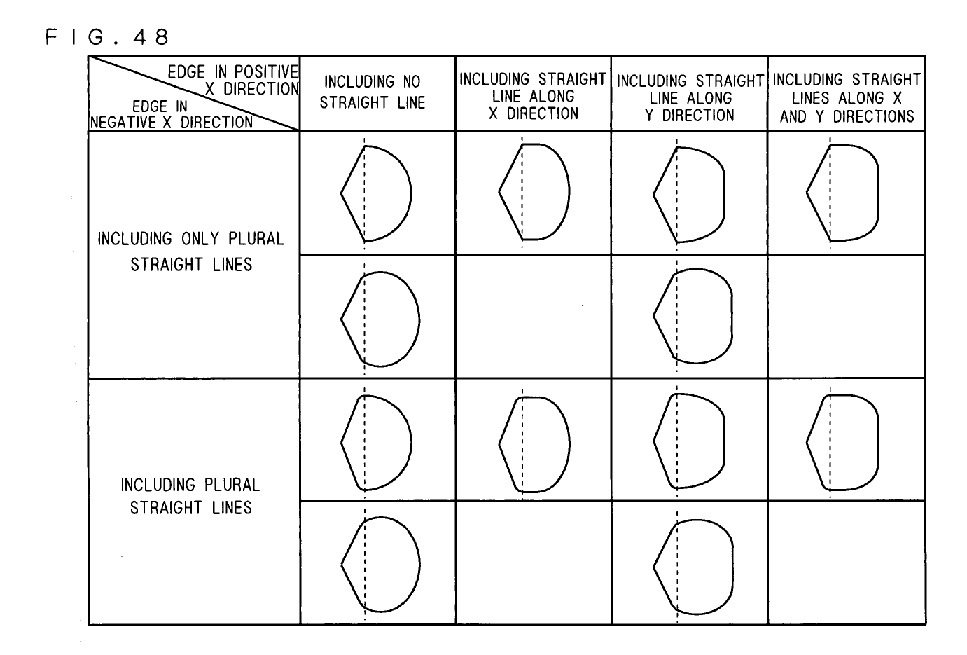

FIG. 45 is a graph including plotted asteroid curves exhibited by the D-shaped magnetic layer illustrated in FIG. 42, which curves are provided when the aspect ratio K and the radius r of the magnetic layer are set to various values. Increase of the radius r results in increase of the threshold value of the strength of the magnetic field Hx which contributes to steepness of the slope of an asteroid curve. On the other hand, reduction of the aspect ratio K serves to steepen a slope of an asteroid curve. Such characteristics can be considered preferable for purposes of reducing a size of a device.

FIGS. 46, 47 and 48 are tables including plan views of various categorized examples of the configuration of the magnetic layer according to the seventh preferred embodiment, i.e., the configuration which is axially symmetrical with respect to an axis parallel to the X direction (along a hard axis) and is asymmetrical with respect to the Y direction (along an easy axis). The table of FIG. 46 shows examples each including an edge which is situated in the negative X side relative to any other edge and includes only a straight line parallel to the Y direction. The table of FIG. 47 shows examples each including an edge situated in the negative X side relative to any other portion (i.e., an edge situated on the left-hand side of a broken line in the drawing sheet, which will be hereinafter referred to simply as “an edge in the negative X side”), which includes only a curve, and examples each including an edge in the negative X side which includes a straight line and curves. The table of FIG. 48 shows examples each including an edge in the negative X side which includes only a plurality of straight lines, and examples each including an edge in the negative X side which includes a plurality of straight lines and a plurality of curves.

Also, in each of the tables of FIGS. 46, 47 and 48, the various examples are categorized into four types of: a type in which a portion situated in the positive X side relative to the edge in the negative X side (which will be hereinafter referred to simply as “a portion in the positive X side”) includes no straight line; a type in which a portion in the positive X side includes a straight line parallel to the X direction; a type in which a portion in the positive X side includes a straight line parallel to the Y direction; and a type in which a portion in the positive X side includes straight lines parallel to the X direction and the Y direction.

The configurations illustrated in FIG. 47 are advantageous over the configurations illustrated in FIG. 46 in that each of the configurations facilitates reversal of a magnetization in view of the inclusion of a rounded comer in the edge in the negative X side. The configurations illustrated in FIG. 48 are advantageous over the configurations illustrated in FIGS. 46 and 47 in that each of the configurations provides for increase in area and is highly resistant to thermal agitation.

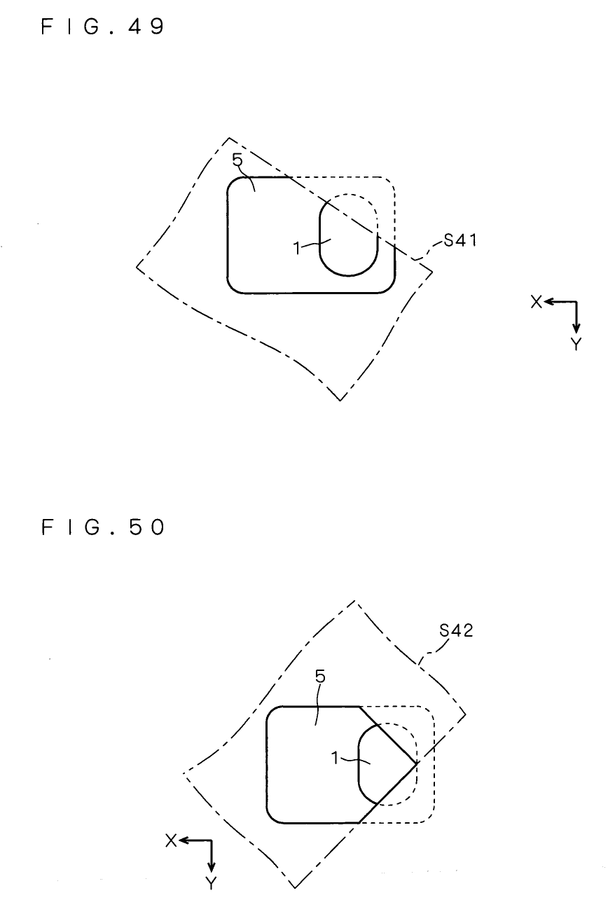

The configurations illustrated in FIG. 48 can be formed by performing the same steps as described in the first through sixth preferred embodiments while using a plurality of masks. For example, the TMR element 1 and the strap 5 configured as illustrated in FIG. 9 are covered with a positive photoresist, and an exposure process is performed on the positive photoresist using a mask S41 illustrated in FIG. 49. The mask S41 includes a straight edge extending along a direction which has components of the positive X direction and the negative Y direction. Subsequently, a development process is performed. As a result, the photoresist can be shaped into a configuration substantially identical to that of the mask S41. Then, by etching the TMR element 1 and the strap 5 using the shaped photoresist as an etch mask, it is possible to shape the TMR element 1 and the strap 5 into configurations illustrated in FIG. 49.

Thereafter, the TMR element 1 and the strap 5 are again covered with a photoresist, and a further exposure process is performed on the photoresist using a mask S42 illustrated in FIG. 50. The mask S42 includes a straight edge extending along a direction which has components of the positive X direction and the positive Y direction. Subsequently, a development process is performed, so that the photoresist can be shaped into a configuration substantially identical to the configuration of the mask S42. Then, by etching the TMR element 1 and the strap 5 using the shaped photoresist as an etch mask, it is possible to shape the TMR element 1 and the strap 5 into configurations illustrated in FIG. 50. In this manner, by utilizing the masks S41 and S42, the edge in the negative X side configured as illustrated in each of the plan views in FIG. 48 can be obtained.

While the invention has been shown and described in detail, the foregoing description is in all aspects illustrative and not restrictive. It is therefore understood that numerous modifications and variations can be devised without departing from the scope of the invention.

What is claimed is:

1. A magnetic recording element comprising:
a magnetic layer showing an S-shaped magnetization distribution when a strength of a magnetic field applied to said magnetic layer along a hard axis of said magnetic layer is higher than a threshold value and showing a C-shaped magnetization distribution when said strength of said magnetic field applied to said magnetic layer along said hard axis is lower than said threshold value.

2. The magnetic recording element according to claim 1, wherein
a configuration of said magnetic layer is symmetrical with respect to an axis parallel to said hard axis and asymmetrical with respect to an easy axis of said magnetic layer.

3. The magnetic recording element according to claim 2, wherein
said configuration of said magnetic layer includes a rounded comer.

4. The magnetic recording element according to claim 2, wherein
said configuration of said magnetic layer includes a plurality of straight lines situated in one of opposite sides of said hard axis.

5. The magnetic recording element according to claim 3, wherein
said configuration of said magnetic layer includes a plurality of straight lines situated in one of opposite sides of said hard axis.

6. A method of manufacturing a magnetic recording device for manufacturing a magnetic recording element and a first conductor connected to said magnetic recording element, said method comprising the step of:
shaping said magnetic recording element and said first conductor into desired configurations by performing a photolithographic process using a same mask.

7. The method of manufacturing a magnetic storage element according to claim 6, wherein
said first conductor extends along a first direction,
said magnetic recording element includes a magnetic layer with a hard axis parallel to said first direction and an easy axis parallel to a second direction which is perpendicular to said first direction, and
said magnetic layer is shaped by performing a photolithographic process using a first mask and a second mask, said first mask being rectangular and including sides parallel to said first direction and said second direction, respectively, and said second mask being the same as is used in said photolithographic process in said step of shaping said magnetic recording element and said first conductor and including an edge parallel to said second direction.

8. The method of manufacturing a magnetic recording element according to claim 6, wherein
said first conductor extends along a first direction,
said magnetic recording element includes a magnetic layer with a hard axis parallel to said first direction and an easy axis parallel to a second direction which is perpendicular to said first direction, and
said magnetic layer is shaped by performing a photolithographic process using a first mask and a second mask, said first mask being rectangular and including sides parallel to said first direction and said second direction, respectively, and said second mask being the same as is used in said photolithographic process in said step of forming said magnetic recording element and said first conductor and including an edge parallel to said first direction.

9. The method of manufacturing a magnetic recording element according to claim 6, further comprising the step of:
manufacturing a second conductor which is connected to said magnetic recording element on an opposite side to said first conductor relative to said magnetic recording element, wherein
said second conductor is also shaped by performing said photolithographic process using said same mask in said step of forming said magnetic recording element and said first conductor.

10. The method of manufacturing a magnetic recording element according to claim 7, wherein
exposure processes are performed on one photoresist using said first mask and said second mask, respectively.

11. The method of manufacturing a magnetic storage element according to claim 8, wherein
exposure processes are performed on one photoresist using said first mask and said second mask, respectively.
